(19) United States
(12) Patent Application Publication
(10) Pub. No.: US 2026/0033087 A1
(43) Pub. Date: Jan. 29, 2026

(54) DISPLAY DEVICE AND DISPLAY PANEL

(71) Applicant: LG Display Co., Ltd., Seoul (KR)

(72) Inventors: Hunyoung CHOI, Daejeon (KR); Taekyoung KIM, Goyang-si (KR); Sunghyun JANG, Paju-si (KR)

(73) Assignee: LG Display Co., Ltd., Seoul (KR)

(21) Appl. No.: 19/255,552

(22) Filed: Jun. 30, 2025

(30) Foreign Application Priority Data
Jul. 25, 2024 (KR) 10-2024-0098874

(51) Int. Cl. H10H 29/49; H01L 25/16; H10H 29/80; H10H 29/855

(52) U.S. Cl. CPC H10H 29/49; H01L 25/167; H10H 29/8325; H10H 29/855

(57) ABSTRACT

A display device and a display panel are discussed. The display device in some examples includes a substrate, a driving chip disposed on the substrate, a plurality of light-emitting elements disposed on the driving chip and electrically connected to the driving chip, a plurality of first electrodes respectively disposed under the plurality of light-emitting elements, and a plurality of solder patterns respectively disposed on upper surfaces of the plurality of first electrodes so as to respectively overlap the plurality of light-emitting elements. Each of the light-emitting elements is bonded to one of the first electrodes by melting of at least one of the solder patterns.

### CROSS-REFERENCE TO RELATED APPLICATION

This application claims priority to Korean Patent Application No. 10-2024-0098874, filed on Jul. 25, 2024 in the Korean Intellectual Property Office, the contents of which in its entirety are herein hereby expressly incorporated by reference into the present application.

### BACKGROUND

### Field

The present disclosure relates to a display device and a display panel, and more specifically, for example, without limitation, to a display device and a display panel capable of reducing a non-transfer issue by increasing a contact area between a bonding layer and a light-emitting element.

### Description of the Related Art

Display devices are applied to various electronic devices such as TV, mobile phones, laptops, and tablets.

The display device includes an organic light-emitting display device (OLED) that emits light by itself, and a liquid crystal display device (LCD) that requires a separate light source.

Recently, a display device including a light-emitting diode (LED) has attracted attention as a next-generation display device. Since the light-emitting diode is made of an inorganic material rather than an organic material, the display device including the light-emitting diode can have a faster lighting speed than that of the liquid crystal display device or the organic light-emitting display device, and can have excellent luminous efficiency, and can display an image with high luminance.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventors have realized that in the transfer technology for transferring the light-emitting element to a panel substrate, the transfer accuracy at which the light-emitting element is transferred to a target position affects a defect of the display device. For example, when the light-emitting element is not transferred to the target position of the panel substrate or is over-transferred to a position out of the target position, this can lead to the defect of the display device. Accordingly, a demand for highly accurate transfer in the transfer of light-emitting elements is increasing.

In order to meet the above-mentioned needs, the inventors of the present disclosure have invented a display device capable of reducing a non-transfer issue by increasing a contact area between a bonding layer and a light-emitting element.

Thus, one technical purpose of an example embodiment of the present disclosure is to provide a display device capable of controlling a size or a thickness of a solder pattern of a bonding layer that bonds and fixes each light-emitting element.

Another technical purpose of an example embodiment of the present disclosure is to provide a display device capable of reducing a non-transfer percentage of a light-emitting element.

Still another technical purpose of an example embodiment of the present disclosure is to provide a display device capable of accurately transferring a light-emitting element to a target position on a panel substrate in a transfer process.

Still yet another technical purpose of the example embodiment of the present disclosure is to provide a display device capable of improving a speed of the transfer process.

Still yet another technical purpose according to an example embodiment of the present disclosure is to provide a display device capable of improving a product yield and productivity.

Purposes according to the present disclosure are not limited to the above-mentioned purpose. Other purposes and advantages according to the present disclosure that are not mentioned can be understood based on following descriptions, and can be more clearly understood based on example embodiments according to the present disclosure. Further, it will be easily understood that the purposes and advantages according to the present disclosure can be realized using means shown in the claims or combinations thereof.

A display device according to example embodiments of the present disclosure can include a substrate; a driving chip disposed on the substrate; a plurality of light-emitting elements disposed on top of the driving chip and electrically connected to the driving chip; a plurality of first electrodes respectively disposed under the plurality of light-emitting elements; and a plurality of solder patterns respectively disposed on upper surfaces of the plurality of first electrodes so as to respectively overlap the plurality of light-emitting elements, wherein each of the light-emitting elements is bonded to each of the first electrodes by each of the solder patterns.

A display device according to example embodiments of the present disclosure can include a substrate; a driving chip disposed on the substrate; a plurality of light-emitting elements disposed on the driving chip and electrically connected to the driving chip; an optical insulating layer covering the plurality of light-emitting elements; and each first electrode disposed under each of the plurality of light-emitting elements, wherein each of the plurality of light-emitting elements has a groove defined in a center area of a bottom thereof, wherein a solder pattern fills the groove and protrudes downwardly beyond a bottom surface of each of the plurality of light-emitting elements such that a protruding portion of the solder pattern contacts the first electrode, wherein each of the plurality of light-emitting elements is bonded to and electrically connected to each first electrode by melting of the solder pattern.

According to an example embodiment of the present disclosure, the light emitting element can be accurately transferred to the target position on the panel substrate in the transfer process.

In addition, according to an example embodiment of the present disclosure, the size or the thickness of the solder pattern of the bonding layer that bonds and fixes each light emitting element in the transfer process can be adjusted. Therefore, the non-transfer percentage of the light emitting element can be reduced.

In addition, according to an example embodiment of the present disclosure, the speed of the transfer process can be improved.

In addition, according to an example embodiment of the present disclosure, the light emitting element can be accurately transferred to the target position, such that the defect of the display device can be reduced.

In addition, according to an example embodiment of the present disclosure, the transfer rate of the transfer process can be improved by preventing the non-transfer of the light-emitting element.

In addition, according to an example embodiment of the present disclosure, as the non-transfer of the light-emitting element is suppressed, the defect of the display device can be minimized.

In addition, according to an example embodiment of the present disclosure, as the defect of the display device is minimized, a decrease in the lifespan of the display device can be prevented.

In addition, according to an example embodiment of the present disclosure, as the defect of the display device is minimized, power consumption of the display device can be lowered.

In addition, according to an example embodiment of the present disclosure, a long-life and low power display device can be realized as the non-transfer of the light-emitting element is suppressed such that the defect is minimized.

In addition, in the display device according to the present disclosure, the non-transfer of the light-emitting element is suppressed and the defect is minimized in the process of manufacturing the display panel, so that the reduction in the lifespan of the display panel can be prevented and the improvement of the quality of the display device can be achieved.

In addition, in the display device according to the present disclosure, the light-emitting element can be stably transferred, thereby improving product quality and securing product reliability.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is an exploded perspective view of a display device according to one or more example embodiments of the present disclosure.

FIG. 2 is a plan view of a display device according to an example embodiment of the present disclosure.

FIG. 3 is an enlarged view of a display device according to an example embodiment of the present disclosure.

FIG. 4 is a diagram illustrating a circuit structure according to an example embodiment of the present disclosure.

FIG. 5 is a plan view of a display device according to an example embodiment of the present disclosure.

FIG. 6 is a plan view of a display device according to an example embodiment of the present disclosure.

FIG. 7 is a plan view of a display device according to an example embodiment of the present disclosure.

FIG. 8 is a cross-sectional view of a display device according to an example embodiment of the present disclosure.

FIG. 9 is a cross-sectional view of a display device according to an example embodiment of the present disclosure.

FIGS. 10 to 13 are diagrams illustrating an apparatus to which a display device according to example embodiments of the present disclosure is applied.

FIG. 14 is a plan view illustrating a bonding area in FIG. 9.

FIG. 15 is a cross-sectional view illustrating a display device according to a first example embodiment of the present disclosure.

FIG. 16 is a cross-sectional view illustrating a display device according to a second example embodiment of the present disclosure.

FIG. 17 is a cross-sectional view illustrating a display device according to a third example embodiment of the present disclosure.

FIG. 18 is a plan view illustrating a display device according to the first example embodiment of the present disclosure.

FIG. 19 is a plan view illustrating a display device according to the second example embodiment of the present disclosure.

FIG. 20 is a plan view illustrating a display device according to the third example embodiment of the present disclosure.

FIG. 21 is a cross-sectional view illustrating light-emitting elements of a display device according to the first example embodiment of the present disclosure.

FIG. 22 is a cross-sectional view illustrating light-emitting elements of a display device according to the second example embodiment of the present disclosure.

FIG. 23 is a cross-sectional view illustrating light-emitting elements of a display device according to the third example embodiment of the present disclosure.

FIG. 24 is a plan view of a display device according to another example embodiment of the present disclosure.

FIG. 25 is a plan view illustrating an area in which one pixel driving circuit among a plurality of pixel driving circuits of FIG. 24 is disposed.

FIG. 26 is a diagram illustrating a touch operation of a display device according to another example embodiment of the present disclosure.

FIG. 27 illustrates an example signal waveform diagram when a display device according to an example embodiment of the present disclosure operates.

FIG. 28 is an enlarged plan view illustrating an area 7 of FIG. 25 according to another example embodiment of the present disclosure.

FIG. 29 is a cross-sectional view taken along a cutting line 8-8 of FIG. 28.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims. Shapes, sizes, dimensions (e.g., length, width, height, thickness, radius, diameter, area, etc.), ratios, angles, numbers, etc. disclosed in the drawings for illustrating embodiments of the present disclosure are illustrative, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “include,” “have,” “comprise,” “contain,” “constitute,” “make up of,” “formed of,” and “consist of” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements can modify the entire list of elements and may not modify the individual elements of the list.

In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to”, or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween.

Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former can directly contact the latter or still another layer, film, area, plate, or the like can be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations. The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. For example, unless otherwise stated or clear from the context, the expression that ‘x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure can work functionally.

When a first component or layer is described as “contacting” or “overlapping” a second component or layer, it should be understood that the first component or layer can directly contact or overlap the second component or layer, or a third component or layer can be interposed between the first and second components or layers that can indirectly contact or overlap each other unless otherwise specified. Further, the term “can” fully encompasses all the meanings and coverages of the term “may” and vice versa.

Hereinafter, various example embodiments of the present disclosure will be described in detail with reference to the accompanying drawings. All the components of each display device according to all embodiments of the present disclosure are operatively coupled and configured.

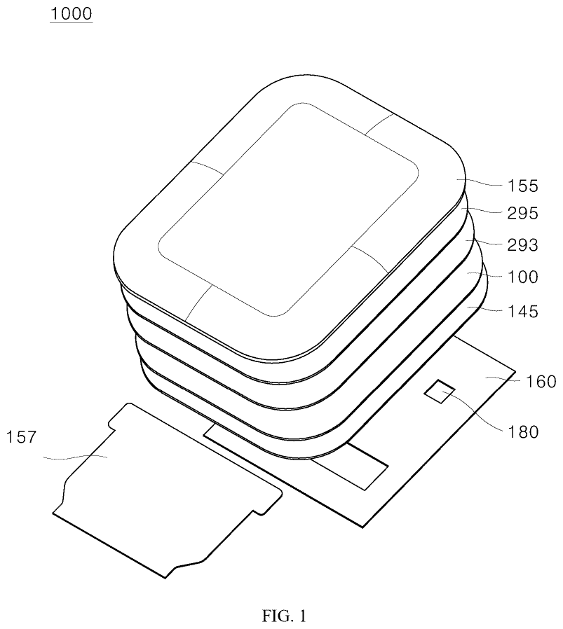

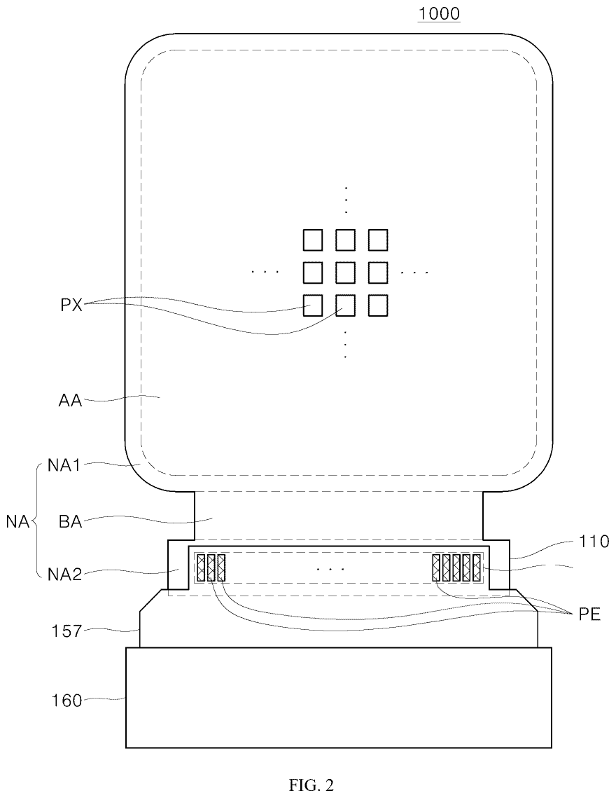

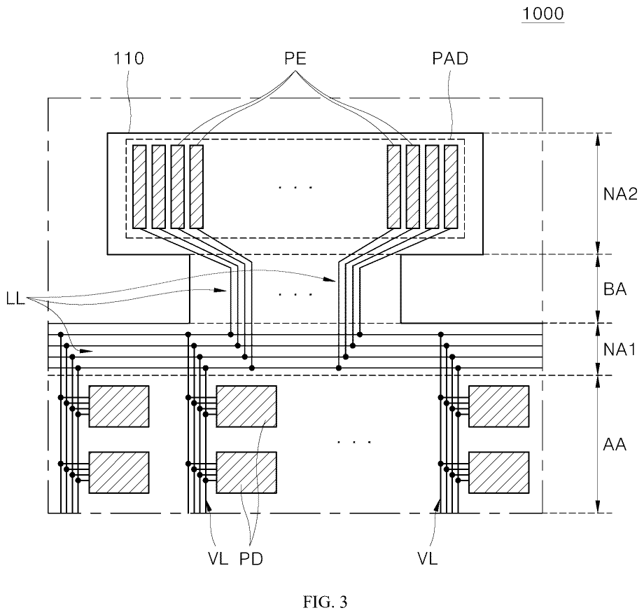

FIG. 1 is an exploded perspective view of a display device according to one or more example embodiments of the present disclosure. FIG. 2 is a plan view of a display device according to an example embodiment of the present disclosure. FIG. 3 is an enlarged view of a display device according to an example embodiment of the present disclosure.

Referring to FIGS. 1 to 3, a display device 1000 according to an example embodiment of the present disclosure can include a display panel 100, a polarizing layer 293, an adhesive layer 295, a cover member 155, a support substrate 145, a flexible circuit board 157, and a printed circuit board 160.

For example, the display device 1000 can include a substrate 110. The substrate 110 can be a member supporting other components of the display device 100. The substrate 110 can be made of an insulating material. For example, the substrate 110 can be made of glass or resin. In addition, the substrate 110 can be made of a material having flexibility. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the substrate 110 can be made of a plastic material having flexibility, such as polyimide (PI). However, example embodiments of the present disclosure are not limited thereto.

The display panel 100 can implement information, a video, and/or an image to be provided to a user. For example, the display panel 100 can include a display area AA (or active area) and a non-display area NA (or non-active area). For example, the substrate 110 can include the display area AA and the non-display area NA. The distinction between the display area AA and the non-display area NA is applied not only to the substrate 110 but also to the display device 1000.

The display area AA can be an area in which an image is displayed. The display area AA can include a plurality of pixels PX. Each of the plurality of pixels PX can be composed of a plurality of sub-pixels. A plurality of light-emitting elements can be disposed in each of the plurality of sub-pixels SP. A type of each of the plurality of light-emitting elements can vary according to a type of the display device 1000. For example, when the display device 1000 is an inorganic light-emitting display device, the light-emitting element can be a light-emitting diode (LED), a micro light-emitting diode (LED), or a mini light-emitting diode (LED). However, example embodiments of the present disclosure are not limited thereto.

The non-display area NA can be an area in which no image is displayed. Various lines and circuits for driving the plurality of pixels PX of the display area AA can be disposed in the non-display area NAA. For example, various wires and driving circuits can be mounted in the non-display area NA, and a pad PAD to which an integrated circuit, a printed circuit, etc. are connected can be disposed in the non-display area NA. However, example embodiments of the present disclosure are not limited thereto.

For example, the driving circuit can be a data driving circuit and/or a gate driving circuit. However, example embodiments of the present disclosure are not limited thereto. Wires to which a control signal for controlling the driving circuits is supplied can be disposed. For example, the control signal can include various timing signals including a clock signal, an input data enable signal, and synchronization signals (for example, a vertical synchronization signal Vsync and a horizontal synchronization signal Hsync), and the like. Here, the horizontal synchronization signal is a signal representing a time taken to display one horizontal line of a screen and the vertical synchronization signal is a signal representing a time taken to display a screen of one frame. The input data enable signal can correspond to a signal indicating a period for which a data voltage is supplied to the pixel. However, example embodiments of the present disclosure are not limited thereto. The control signal can be received via the pad PAD. For example, link lines LL for transmitting signals can be disposed in the non-display area NA. For example, driving components such as a flexible printed circuit board 157 and a printed circuit board 160 can be connected to the pad PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA is an area extending from at least one of a plurality of sides of the first non-display area NA1 and can be a bendable area. The second non-display area NA2 can be an area extending from the bending area BA, and the pad PAD can be disposed in the second non-display area. For example, the bending area BA can be in a bent state, and the remaining area of the substrate 110 except for the bending area BA can be in a flat state. In this case, as the bending area BA is bent, the second non-display area NA2 can be located on a rear surface of the display area AA. However, example embodiments of the present disclosure are not limited thereto.

For example, the non-display area NA can include a first non-display area, a second non-display area, a third non-display area, and a fourth non-display area. The first non-display area can be located outside of the display area AA in the column direction. The second non-display area can be located outside of the display area AA in a row direction (or first direction). The third non-display area can be located outside of the display area AA in the column direction (or second direction) and located opposite to the first non-display area. The fourth non-display area can be located outside of the display area AA in the row direction and located opposite to the second non-display area. The first non-display area among the first to fourth non-display areas can include a pad area to which a driving circuit is connected or bonded. The second to fourth non-display areas that do not include the pad area among the first to fourth non-display areas can have a very small size, but aspects of the present disclosure are not limited thereto.

The display area AA of the substrate 110 or the display device 1000 can be formed in various shapes according to the designs of the display device 1000. For example, the display area AA can be formed in a rectangular shape having four corners of a round shape. However, example embodiments of the present disclosure are not limited thereto. In another example, the display area AA can be formed in a rectangular shape in which four corners have a right angle or a circular shape. However, example embodiments of the present disclosure are not limited thereto.

According to the present disclosure, a width of the second non-display area NA2 in which a plurality of pad electrodes PE are disposed can be greater than a width of the bending area BA in which only a plurality of link lines LL are disposed. In addition, the width of the display area AA in which the plurality of sub-pixels are disposed can be greater than the width of the bending area BA in which only the plurality of link lines LL are disposed. Although the width of the bending area BA is illustrated as being smaller than the width of the remaining area of the substrate 110 in the drawing, a shape of the substrate 110 including the bending area BA is merely an example, and example embodiments of the present disclosure are not limited thereto.

Referring to FIG. 3, a plurality of pixel driving circuits PD can be disposed in the display area AA. The plurality of pixel driving circuits PD can be circuits for driving the light-emitting elements of the plurality of sub-pixels. Each of the plurality of pixel driving circuits PD can include a plurality of transistors including a driving transistor, a storage capacitor, etc., and can control an emission operation of the plurality of light-emitting elements by supplying a control signal, a power, and a driving current to the light-emitting elements of the plurality of sub-pixels. For example, the pixel driving circuit PD can include a power line and a signal line for controlling the emission on/off and/or emission time of the light-emitting element. For example, each of the plurality of pixel driving circuits PD can be a driver manufactured using a metal-oxide-silicon field effect transistor (MOSFET) manufacturing process and disposed on a semiconductor substrate. However, example embodiments of the present disclosure are not limited thereto. A driver can include the plurality of pixel driving circuits PD and can drive the plurality of sub-pixels. For example, the plurality of pixel driving circuits PD can include a micro driver (uDriver). However, example embodiments of the present disclosure are not limited thereto. For example, each of the plurality of pixel driving circuits PD can include a driving chip. However, example embodiments of the present disclosure are not limited thereto. The micro driver can be implemented in a form of a chip.

Referring to FIG. 1 and FIG. 2, the flexible circuit board 157 and the printed circuit board 160 can be disposed under the display panel 100. The flexible circuit board 157 and the printed circuit board 160 can be disposed at least at one edge of the display panel 100. However, example embodiments of the present disclosure are not limited thereto. One side of the flexible circuit board 157 can be attached to the display panel 100 and the other side thereof can be attached to the printed circuit board 160. However, example embodiments of the present disclosure are not limited thereto. The flexible circuit board 157 can be a flexible film. However, example embodiments of the present disclosure are not limited thereto.

The pad PAD including a plurality of pad electrodes PE can be disposed in the second non-display area NA2. A driving component including one or more flexible circuit boards (or flexible films) 157 and the printed circuit board 160 can be attached or bonded to the pad PAD. The plurality of pad electrodes PE of the pad PAD can be electrically connected to one or more flexible circuit boards (or flexible films) 157, and can transmit various signals (or power) from the printed circuit board 160 and the flexible circuit boards (or flexible films) 157 to the plurality of pixel driving circuits PD of the display area AA.

The flexible circuit board (or flexible film) 157 can be a film in which various components are disposed on a flexible base film. For example, a driving IC such as a gate driver IC or a data driver IC can be disposed on the flexible circuit board (or flexible film) 157. However, example embodiments of the present disclosure are not limited thereto. The driving IC DT can be a component that processes data for displaying an image and a driving signal. The driving IC DT can be disposed in a manner such as a Chip On Glass (COG), a Chip On Film (COF), or a Tape Carrier Package (TCP) according to a mounted manner. However, example embodiments of the present disclosure are not limited thereto. The flexible circuit board (or flexible film) 157 can be attached or bonded to the plurality of pad electrodes PE via a conductive adhesive layer. However, example embodiments of the present disclosure are not limited thereto.

The printed circuit board 160 can be electrically connected to one or more flexible circuit boards (or flexible films) 157 and can be a component that supplies a signal to the driving IC. The printed circuit board 160 can be disposed on one side of the flexible circuit board (or flexible film) 157 so as to be electrically connected to the flexible circuit board (or flexible film) 157. Various components for supplying various signals to the driving IC can be disposed on the printed circuit board 160. For example, various components such as a timing controller, a power supply unit, a memory, or a processor can be disposed on the printed circuit board 160. For example, the printed circuit board 160 can include a power management integrated circuit (PMIC). However, example embodiments of the present disclosure are not limited thereto.

The printed circuit board 160 can include at least one hole 180. However, example embodiments of the present disclosure are not limited thereto. An internal component for sensing ambient light or temperature that can be provided to the plurality of sensors can be disposed in an area corresponding to the at least one hole 180. For example, the internal component can include an ALS (Ambient light sensor), a temperature sensor, etc. However, example embodiments of the present disclosure are not limited thereto. For example, the hole 180 can be a transmission hole or the like. However, example embodiments of the present disclosure are not limited thereto.

Referring to FIG. 1, the polarizing layer 293 can be disposed on the display panel 100. The polarizing layer 293 can prevent or reduce light generated from an external light source from entering the display panel 100 and thus affecting the light-emitting element or the like.

The cover member 155 can be disposed on the polarizing layer 293. The cover member 155 can be a member for protecting the display panel 100. The adhesive layer 295 can be disposed between the polarizing layer 293 and the cover member 155. The cover member 155 can be attached to the display panel 100 via the adhesive layer 295. The adhesive layer 295 can include an OCA (Optically clear adhesive), an OCR (Optically clear resin), a PSA (Pressure sensitive adhesive), etc. However, example embodiments of the present disclosure are not limited thereto.

The support substrate 145 can be disposed between the display panel 100 and the printed circuit board 160. The support substrate 145 can reinforce the rigidity of the display panel 100. The support substrate 145 can be a back plate. However, example embodiments of the present disclosure are not limited thereto.

Referring to FIGS. 1 to 3, the plurality of link lines LL can be disposed in the non-display area NA. The plurality of link lines LL can be lines for transmitting various signals from one or more flexible circuit boards (or flexible films) 157 and the printed circuit board 160 to the display area AA. The plurality of link lines LL can extend from the plurality of pad electrodes PE of the second non-display area NA2 toward the bending area BA and the first non-display area NA1 and can be electrically connected to the plurality of driving lines VL of the display area AA. The plurality of pixel driving circuits PD can be driven upon receiving signals from one or more flexible circuit boards (or flexible films) 157 and the printed circuit boards 160 via driving lines VL of the display area AA and the link lines LL of the non-display area NA.

For example, a plurality of driving lines VL together with the plurality of link lines LL can transmit signals output from the flexible circuit board (or flexible film) 157 and the printed circuit board 160 to the plurality of pixel driving circuits PD. The plurality of driving lines VL can be disposed in the display area AA and can be electrically connected to each of the plurality of pixel driving circuits PD. The plurality of driving lines VL can extend from the display area AA toward the non-display area NA and can be electrically connected to the plurality of link lines LL. Accordingly, the signals output from the flexible circuit board (or flexible film) 157 and the printed circuit board 160 can be transmitted to each of the plurality of pixel driving circuits PD via the plurality of link lines LL and the plurality of driving lines VL.

As the bending area BA is bent, a portion of each of the plurality of link lines LL can also be bent. Thus, stress is concentrated on a portion of the bent link line LL, and accordingly, a crack can occur in the link line LL. Accordingly, the plurality of link lines LL can be made of a conductive material having excellent ductility to reduce the cracks occurring when the bending area BA is bent. For example, the plurality of link lines LL can be made of a conductive material having excellent ductility, such as gold (Au), silver (Ag), aluminum (Al), etc. However, example embodiments of the present disclosure are not limited thereto. In addition, the plurality of link lines LL can be made of one of various conductive materials used in the display area AA. For example, the plurality of link lines LL can be made of molybdenum (Mo), chromium (Cr), titanium (Ti), nickel (Ni), neodymium (Nd), copper (Cu), an alloy thereof, or an alloy of silver (Ag) and magnesium (Mg). However, example embodiments of the present disclosure are not limited thereto. The plurality of link lines LL can be configured in a multilayer structure including various conductive materials. For example, the plurality of link lines LL can be configured in a triple layer structure of a titanium (Ti) layer/aluminum (Al) layer/titanium (Ti) layer. However, example embodiments of the present disclosure are not limited thereto.

The plurality of link lines LL can be formed in various shapes to reduce the stress. At least a portion of each of the plurality of link lines LL disposed on the bending area BA can extend in the same direction as an extending direction of the bending area BA, or can extend in a direction different from the extending direction of the bending area BA to reduce the stress. For example, when the bending area BA extends in one direction from the first non-display area NA1 toward the second non-display area NA2, at least a portion of the link line LL disposed on the bending area BA can extend in a direction inclined with respect to the one direction. In another example, at least a portion of each of the plurality of link lines LL can be formed in each of patterns of various shapes. For example, at least a portion of each of the plurality of link lines LL disposed on the bending area BA can have a shape in which conductive patterns having at least one of a diamond shape, a rhombus shape, a trapezoidal shape, a triangular wave shape, a sawtooth wave shape, a sine wave shape, a circular shape, and an omega (Ω) shape are repeatedly arranged. However, example embodiments of the present disclosure are not limited thereto. Therefore, in order to reduce or minimize the stress concentrated on the plurality of link lines LL and the resulting crack, the shape of each of the plurality of link lines LL can be formed in various shapes including the above-described shape. However, example embodiments of the present disclosure are not limited thereto.

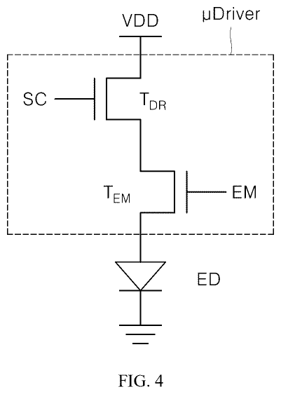

FIG. 4 is a diagram illustrating a circuit structure according to an example embodiment of the present disclosure.

Particularly, FIG. 4 illustrates that one light-emitting element ED is connected to the micro driver μDriver. However, example embodiments of the present disclosure are not limited thereto. For example, eight light-emitting elements ED can be simultaneously connected to one micro driver μDriver. In another example, 16 light-emitting elements ED can simultaneously be connected to one micro driver μDriver, or 32 light-emitting elements ED or 64 light-emitting elements ED can be simultaneously connected to one micro driver μDriver or 64 light-emitting elements ED or 256 light-emitting elements ED can be simultaneously connected to one micro driver μDriver or 768 light-emitting elements ED can be simultaneously connected to one micro driver μDriver. The light-emitting element ED can be a micro light-emitting element μLED.

Referring to FIG. 4, one micro driver μDriver can include a driving transistor TDR and a light-emission transistor TEM. However, example embodiments of the present disclosure are not limited thereto.

For example, a high potential power voltage VDD can be applied to a first electrode of the driving transistor TDR, a first electrode of the light-emission transistor TEM can be connected to a second electrode of the driving transistor TDR, and a scan signal SC can be applied to a gate electrode of the driving transistor TDR. The scan signal SC applied to the gate electrode of the driving transistor TDR is a direct current power, and a fixed reference voltage Vref can be applied thereto every frame. However, example embodiments of the present disclosure are not limited thereto.

The second electrode of the driving transistor TDR can be connected to the first electrode of the light-emission transistor TEM, the light-emitting element ED can be connected to a second electrode of the light-emission transistor TEM, and the light-emission signal EM can be applied to a gate electrode of the light-emission transistor TEM. The light-emission signal EM applied to the gate electrode of the light-emission transistor TEM can be a pulse width modulation signal that varies in every frame. However, example embodiments of the present disclosure are not limited thereto.

The light-emitting element ED can have a first electrode connected to the second electrode of the light-emission transistor TEM, and a second electrode connected to the ground. For example, the first electrode thereof can be an anode electrode, and the second electrode thereof can be a cathode electrode. However, example embodiments of the present disclosure are not limited thereto.

Each of the driving transistor TDR and the light-emission transistor TEM can be an n-type transistor or a p-type transistor.

In the micro driver μDriver, the driving transistor TDR can be turned on based on the scan signal SC applied thereto from a timing controller T-CON, and the light-emission transistor TEM can be turned on based on the light-emission signal EM. Accordingly, the driving current is applied to the light-emitting element ED via the driving transistor TDR and the light-emission transistor TEM based on the high potential power voltage VDD applied to the first electrode of the driving transistor TDR, so that the light-emitting element ED can emit light.

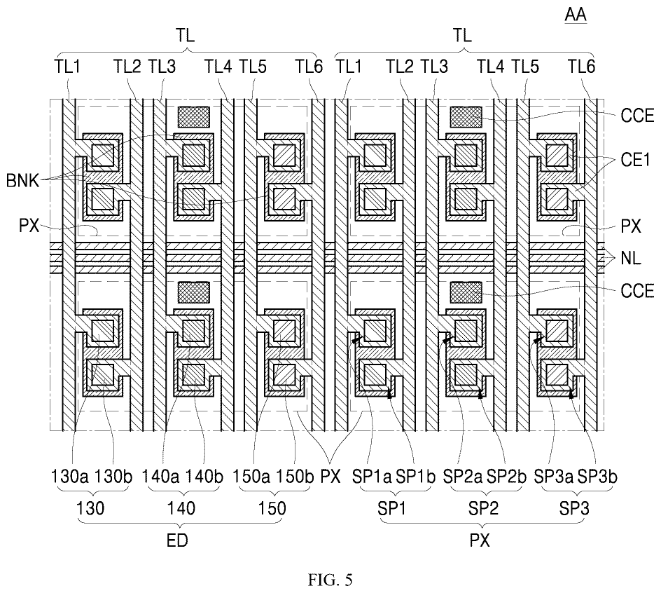

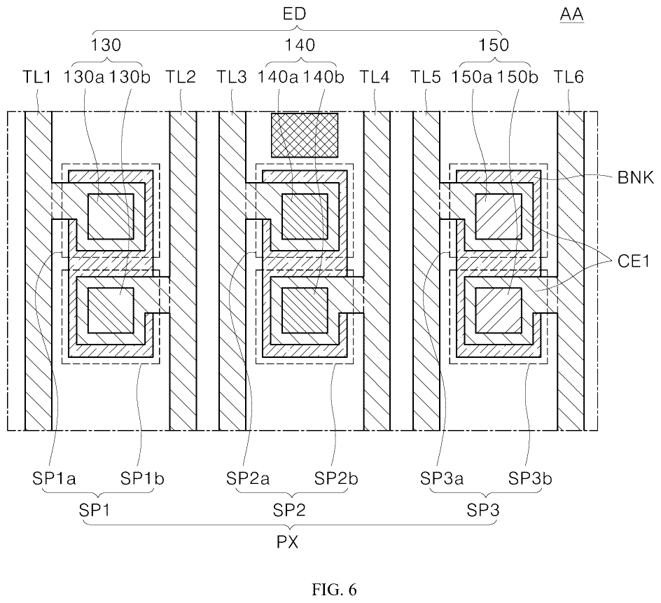

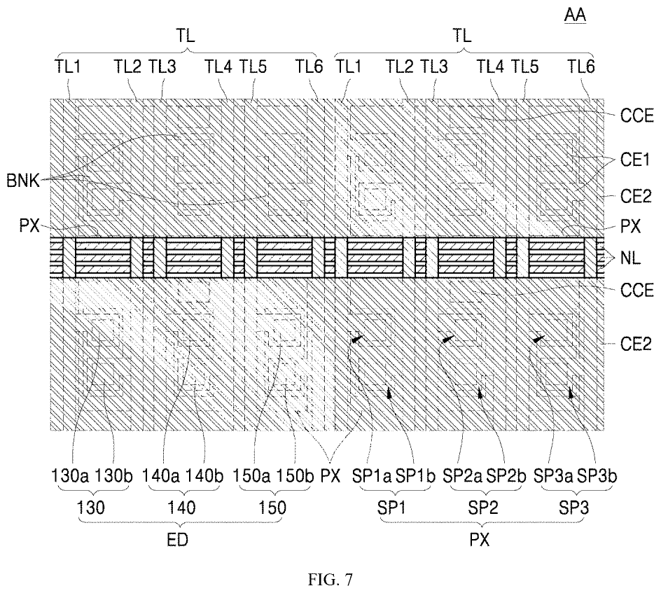

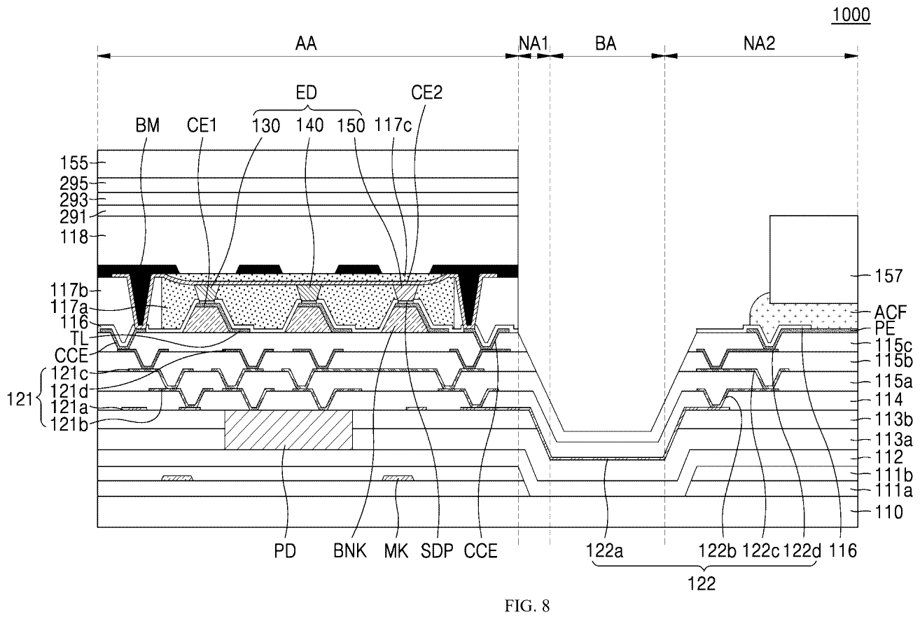

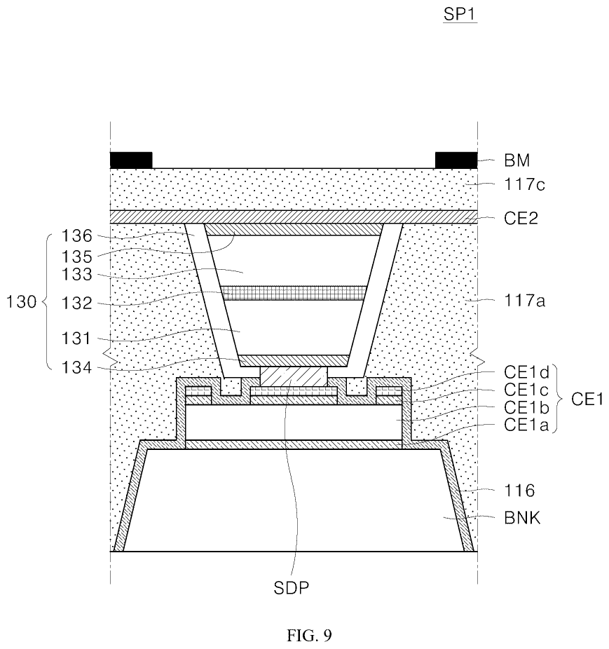

FIG. 5, FIG. 6 and FIG. 7 are plan views of a display device according to an example embodiment of the present disclosure. FIGS. 8 and 9 are cross-sectional views of a display device according to an example embodiment of the present disclosure.

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. FIGS. 5 and 6 illustrate a plurality of signal lines TL, a plurality of communication lines NL, a plurality of first electrodes CE1, a plurality of banks BNK, and a plurality of light-emitting elements ED. However, example embodiments of the present disclosure are not limited thereto. FIG. 7 is an enlarged plan view in which a plurality of second electrodes CE2 are additionally disposed in FIG. 5.

Referring to FIGS. 5, 6, and 9, a plurality of pixels PX, each including a plurality of sub-pixels, can be disposed in the display area AA. Each of the plurality of sub-pixels includes a light-emitting element ED, and can independently emit light. The plurality of sub-pixels can be arranged in a plurality of rows and a plurality of columns and thus can be arranged in a matrix form. However, example embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2, and the third sub-pixel SP3 can be a red sub-pixel, another thereof can be a green sub-pixel, and the other thereof can be a blue sub-pixel. In some example embodiments, plurality of sub-pixels can further includes a fourth sub-pixel, and the fourth sub-pixel can be a white sub-pixel A type of each of the plurality of sub-pixels is an example, and example embodiments of the present disclosure are not limited thereto.

For example, the plurality of subpixels of the pixel PX can be variously modified in colors and configurations, as necessary. For example, the plurality of subpixels can include red, green, and blue subpixels, in which the red, green, and blue subpixels can be disposed in a repeated manner. Alternatively, the plurality of subpixels can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can include a (1-1)-th sub-pixel SP1a and a (1-2)-th sub-pixel SP1b. The pair of second sub-pixels SP2 can include a (2-1)-th sub-pixel SP2a and a (2-2)-th sub-pixel SP2b. The pair of third sub-pixels SP3 can include a (3-1)-th sub-pixel SP3a and a (3-2)-th sub-pixel SP3b. For example, one pixel PX can include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, example embodiments of the present disclosure are not limited thereto.

The plurality of sub-pixels constituting one pixel PX can be arranged in various manner. In one example, in one pixel PX, a pair of first sub-pixels SP1 can be arranged in the same column, a pair of second sub-pixels SP2 can be arranged in the same column, and a pair of third sub-pixels SP3 can be arranged in the same column. The first sub-pixel SP1, the second sub-pixel SP2, and the third sub-pixel SP3 can be arranged in the same row. Alternatively, in one pixel PX, a pair of first sub-pixels SP1 can be arranged in the same row, a pair of second sub-pixels SP2 can be arranged in the same row, and a pair of third sub-pixels SP3 can be arranged in the same row. The first sub-pixel SP1, the second sub-pixel SP2, and the third sub-pixel SP3 can be arranged in the same column. The number and arrangement of the plurality of sub-pixels constituting one pixel PX are examples, and example embodiments of the present disclosure are not limited thereto.

A plurality of signal lines TL can be disposed in an area between adjacent ones of the plurality of sub-pixels. The plurality of signal lines TL can extend in the column direction while being disposed between adjacent ones of the plurality of sub-pixels. The plurality of signal lines TL can be lines for transmitting an anode voltage from the pixel driving circuit PD to the plurality of sub-pixels. For example, the plurality of signal lines TL can be electrically connected to the plurality of pixel driving circuits PD and the first electrodes CE1 of the plurality of sub-pixels. The anode voltage output from the pixel driving circuit PD can be transmitted to the first electrodes CE1 of the plurality of sub-pixels via the plurality of signal lines TL. For example, the first electrode CE1 can be an electrode electrically connected to the anode electrode 134 of the light-emitting element ED. Accordingly, the anode voltage from the signal line TL can be transmitted to the anode electrode 134 of the light-emitting element ED via the first electrode CE1.

Therefore, a structure of the display device 1000 can be simplified using the pixel driving circuit PD in which the plurality of pixel circuits are integrated with each other, instead of forming a plurality of transistors and a storage capacitor in each of the plurality of sub-pixels. In addition, as circuits respectively disposed in the plurality of sub-pixels are integrated into one pixel driving circuit PD, high-efficiency low-power operation of the display device can be achieved.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to the pair of first sub-pixels SP1, respectively. The third signal line TL3 and the fourth signal line TL4 can be electrically connected to the pair of second sub-pixels SP2, respectively. The fifth signal line TL5 and the sixth signal line TL6 can be electrically connected to the pair of third sub-pixels SP3, respectively.

The first signal line TL1 can be disposed on one side of the pair of first sub-pixels SP1, and the second signal line TL2 can be disposed on the other side of the pair of first sub-pixels SP1. The first signal line TL1 can be electrically connected to one first sub-pixel SP1 of the pair of first sub-pixels SP1, for example, the first electrode CE1 of the (1-1)-th sub-pixel SP1a. The second signal line TL2 can be electrically connected to the other first sub-pixel SP1 of the pair of first sub-pixels SP1, for example, the first electrode CE1 of the (1-2)-th sub-pixel SP1b.

The third signal line TL3 can be disposed on one side of the pair of second sub-pixels SP2, and the fourth signal line TL4 can be disposed on the other side of the pair of second sub-pixels SP2. For example, the third signal line TL3 can be disposed adjacent to the second signal line TL2. The third signal line TL3 can be electrically connected to one second sub-pixel SP2 of the pair of second sub-pixels SP2, for example, the first electrode CE1 of the (2-1)-th sub-pixel SP2a. The fourth signal line TL4 can be electrically connected to the other second sub-pixel SP2 of the pair of second sub-pixels SP2, for example, the first electrode CE1 of the (2-2)-th sub-pixel SP2b.

The fifth signal line TL5 can be disposed on one side of the pair of third sub-pixels SP3, and a sixth signal line TL6 can be disposed on the other side of the pair of third sub-pixels SP3. For example, the fifth signal line TL5 can be disposed adjacent to the fourth signal line TL4. The sixth signal line TL6 can be disposed adjacent to the first signal line TL1 connected to the pixel PX adjacent thereto. The fifth signal line TL5 can be electrically connected to one third sub-pixel SP3 of the pair of third sub-pixels SP3, for example, the first electrode CE1 of the (3-1)-th sub-pixel SP3a. The sixth signal line TL6 can be electrically connected to the other third sub-pixel SP3 of the pair of third sub-pixels SP3, for example, the first electrode CE1 of the (3-2)-th sub-pixel SP3b.

As shown in FIG. 5, a first pixel includes a pair of first sub-pixels SP1, a pair of second sub-pixels SP2, and a pair of third sub-pixels SP3, wherein, the pair of first sub-pixels SP1 includes a (1-1)-th sub-pixel SP1a and a (1-2)-th sub-pixel SP1b, the pair of second sub-pixels SP2 includes a (2-1)-th sub-pixel SP2a and a (2-2)-th sub-pixel SP2b, and the pair of third sub-pixels SP3 includes a (3-1)-th sub-pixel SP3a and a (3-2)-th sub-pixel SP3b. The first signal line TL1 can be electrically connected to the first electrode CE1 of the (1-1)-th sub-pixel SP1a, the second signal line TL2 can be electrically connected to the first electrode CE1 of the (1-2)-th sub-pixel SP1b, the third signal line TL3 can be electrically connected to the first electrode CE1 of the (2-1)-th sub-pixel SP2a, the fourth signal line TL4 can be electrically connected to the first electrode CE1 of the (2-2)-th sub-pixel SP2b, the fifth signal line TL5 can be electrically connected to the first electrode CE1 of the (3-1)-th sub-pixel SP3a, and the sixth signal line TL6 can be electrically connected to the first electrode CE1 of the (3-2)-th sub-pixel SP3b. Meanwhile, the first signal line TL1 connected to the first pixel is adjacent to the sixth signal line TL6 connected to a second pixel adjacent to the first pixel. However, the present disclosure is not limited thereto.

Each of the plurality of signal lines TL can be made of a conductive material. For example, each of the plurality of signal lines TL can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, example embodiments of the present disclosure are not limited thereto. In another example, each of the plurality of signal lines TL can have a multilayer structure made of a conductive material. For example, each of the plurality of signal lines TL can have a multilayer structure of a titanium (Ti) layer/aluminum (Al) layer/titanium (Ti) layer/indium tin oxide (ITO) layer. However, example embodiments of the present disclosure are not limited thereto.

A plurality of communication lines NL can be disposed in an area between adjacent ones of the plurality of pixels PX. The plurality of communication lines NL can extend in the row direction while being disposed in an area between adjacent ones of the plurality of pixels PX. The plurality of communication lines NL can be disposed in an area between adjacent ones of the plurality of second electrodes CE2 and may not overlap the plurality of second electrodes CE2. For example, the plurality of communication lines NL can be lines used for short-range communication such as near field communication (NFC). The plurality of communication lines NL can function as antennas. For example, the plurality of communication lines NL can be a plurality of connection lines, etc. However, example embodiments of the present disclosure are not limited thereto.

According to the present disclosure, a bank BNK can be disposed in each of the plurality of sub-pixels. The bank BNK can be formed of an opaque material (for example, black) in order to prevent light interference between adjacent pixels. In this case, the bank BNK can include a light shielding material constituted by at least one of a color pigment, organic black, or carbon, without being limited thereto.

For example, the bank BNK can be formed of an organic layer such as an acryl-based material, an epoxy-based material, a phenolic-based material, a polyamide-based material, or a polyimide-based material. Meanwhile, the bank BNK can include an inorganic insulating material, such as silicon nitride (SiNx) or silicon oxide (SiOx), or the bank BNK can be formed of black resin. However, the present disclosure is not limited thereto.

Each of the plurality of banks BNK can be a structure in which each of the plurality of light-emitting elements ED is seated. The plurality of banks BNK can guide positions of the plurality of light-emitting elements ED in a transfer process of transferring the plurality of light-emitting elements ED to the substrate, respectively. In the transfer process of the plurality of light-emitting elements ED thereto, the plurality of light-emitting elements ED can be transferred onto the plurality of banks BNK, respectively. The plurality of banks BNK can be bank patterns, structures, etc. However, example embodiments of the present disclosure are not limited thereto.

The bank BNK of the first sub-pixel SP1, the bank BNK of the second sub-pixel SP2, and the bank BNK of the third sub-pixel SP3 can be spaced apart from each other. The bank BNK of the first sub-pixel SP1, the bank BNK of the second sub-pixel SP2, and the bank BNK of the third sub-pixel SP3 can be constructed to be isolated from each other. Accordingly, the banks BNK of the first sub-pixel SP1, the second sub-pixel SP2, and the third sub-pixel SP3 to which different types of light-emitting elements ED are transferred, respectively can be easily identified.

The bank BNK of the (1-1)-th sub-pixel SP1a and the bank BNK of the (1-2)-th sub-pixel SP1b can be connected to each other, or can be spaced apart or isolated from each other. For example, the bank BNK of the (1-1)-th sub-pixel SP1a and the bank BNK of the (1-2)-th sub-pixel SP1b in which the light-emitting elements ED of the same type are disposed, respectively can be connected to each other, or can be spaced apart or isolated from each other in consideration of a design such as a transfer process requirement. In addition, the bank BNK of the (2-1)-th sub-pixel SP2a and the bank BNK of the (2-2)-th sub-pixel SP2b can be connected to each other, or can be spaced apart or isolated from each other. The bank BNK of the (3-1)-th sub-pixel SP3a and the bank BNK of the (3-2)-th sub-pixel SP3b can be connected to each other, or can be spaced apart or isolated from each other. Accordingly, the banks BNK of the pair of first sub-pixels SP1, the banks BNK of the pair of second sub-pixels SP2, and the banks BNK of the pair of third sub-pixels SP3 can be variously formed. Example embodiments of the present disclosure are not limited thereto.

For example, each of the plurality of banks BNK can be made of an organic insulating material. Each of the plurality of banks BNK can be formed as a single layer or multiple layers made of an organic insulating material. For example, each of the plurality of banks BNK can be made of photoresist, polyimide (PI), or an acryl-based material. However, example embodiments of the present disclosure are not limited thereto.

The first electrode CE1 can be disposed in each of the plurality of sub-pixels SP. The first electrode CE1 can be disposed on the bank BNK. The first electrode CE1 can be electrically connected to one signal line TL among the plurality of signal lines TL. At least a portion of the first electrode CE1 can extend outwardly of the bank BNK and can be electrically connected to the signal line TL closest to the first electrode CE1. For example, a portion of the first electrode CE1 of the (1-1)-th sub-pixel SP1a can extend to one side area of the (1-1)-th sub-pixel SP1a so as to be electrically connected to the first signal line TL1, and a portion of the first electrode CE1 of the (1-2)-th sub-pixel SP1b can extend to the other side area of the (1-2)-th sub-pixel SP1b so as to be electrically connected to the second signal line TL2. A portion of the first electrode CE1 of the (2-1)-th sub-pixel SP2a can extend to one side area of the (2-1)-th sub-pixel SP2a so as to be electrically connected to the third signal line TL3, and a portion of the first electrode CE1 of the (2-1)-th sub-pixel SP2b can extend to the other side area of the (2-1)-th sub-pixel SP2b so as to be electrically connected to the fourth signal line TL4. A portion of the first electrode CE1 of the (3-1)-th sub-pixel SP3a can extend to one side area of the (3-1)-th sub-pixel SP3a so as to be electrically connected to the fifth signal line TL5, and a portion of the first electrode CE1 of the (3-2)-th sub-pixel SP3b can extend to the other side area of the (3-2)-th sub-pixel SP3b so as to be electrically connected to the sixth signal line TL6. However, example embodiments of the present disclosure are not limited thereto.

The first electrode CE1 can be electrically connected to the anode electrode 134 of the light-emitting element ED, and can transmit an anode voltage from the pixel driving circuit PD to the light-emitting element ED via the signal line TL. Different voltages can be respectively applied to the first electrodes CE1 of the plurality of sub-pixels based on a displayed image. For example, different voltages can be applied to the first electrodes CE1 of the plurality of sub-pixels SP, respectively. Accordingly, the first electrode CE1 can be a pixel electrode, and example embodiments of the present disclosure are not limited thereto.

The first electrode CE1 can be made of a conductive material. For example, the first electrode CE1 can be integrally formed with the plurality of signal lines TL. For example, the first electrode CE1 can be made of the same conductive material as that of each of the plurality of signal lines TL. However, example embodiments of the present disclosure are not limited thereto. For example, the first electrode CE1 can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, example embodiments of the present disclosure are not limited thereto. In another example, the first electrode CE1 can be configured to have a multilayer structure made of a conductive material. For example, each of the plurality of first electrodes CE1 can have a multilayer structure of a titanium (Ti) layer/aluminum (Al) layer/titanium (Ti) layer/indium tin oxide (ITO) layer. However, example embodiments of the present disclosure are not limited thereto.

The light-emitting element ED can be disposed in each of the plurality of sub-pixels. The plurality of light-emitting elements ED can be one of a light-emitting diode (LED) or a micro light-emitting diode (LED). However, example embodiments of the present disclosure are not limited thereto. The plurality of light-emitting elements ED can be disposed on the bank BNK and the first electrode CE1. The plurality of light-emitting elements ED can be disposed on the first electrode CE1 and can be electrically connected to the first electrode CE1. Accordingly, the light-emitting element ED can receive the anode voltage from the pixel driving circuit PD via the signal line TL and the first electrode CE1 to emit light.

The plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another thereof can be a green light-emitting element, and the other thereof can be a blue light-emitting element. For example, the first light-emitting element 130 is a red light-emitting element, the second light-emitting element 140 is a green light-emitting element, and the third light-emitting element 150 is a blue light-emitting element. However, example embodiments of the present disclosure are not limited thereto. Accordingly, various colors of light including white can be implemented by combining red light, green light, and blue light respectively emitted from the plurality of light-emitting elements ED from each other. The type of each of the plurality of light-emitting elements ED is merely an example, and example embodiments of the present disclosure are not limited thereto.

The first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5-7 and 9 together, the second electrode CE2 can be disposed in each of the plurality of sub-pixels SP. The second electrode CE2 can be disposed on the light-emitting element ED. The second electrode CE2 can be electrically connected to the pixel driving circuit PD via a plurality of contact electrodes CCE.

For example, the second electrode CE2 can be electrically connected to the cathode electrode 135 of the light-emitting element ED to transmit the cathode voltage from the pixel driving circuit PD to the light-emitting element ED. The same cathode voltage can be applied to the second electrodes CE2 of the plurality of sub-pixels SP. For example, the same voltage can be applied to the second electrodes CE2 of the plurality of sub-pixels and the cathode electrode 135 of the light-emitting element ED. Accordingly, the second electrode CE2 can be a common electrode. However, example embodiments of the present disclosure are not limited thereto.

At least some of the plurality of sub-pixels can share the second electrode CE2 with each other. At least some of the second electrodes CE2 of the plurality of sub-pixels SP can be electrically connected to each other. As the same voltage is applied to the second electrodes CE2, the second electrode CE2 can be shared by the at least some sub-pixels. For example, the second electrodes CE2 of at least some pixels PX among the plurality of pixels PX disposed in the same row can be connected to each other. For example, one second electrode CE2 can be disposed in the plurality of pixels PX. For example, one second electrode CE2 can be disposed in a combination of n sub-pixels.

For example, some of the respective second electrodes CE2 of the plurality of sub-pixels SP can be spaced apart or isolated from each other. For example, the second electrode CE2 connected to the pixels PX of an n-th row and the second electrode CE2 connected to the pixels PX of an (n+1)-th row can be spaced apart or isolated from each other. For example, adjacent ones of the plurality of second electrodes CE2 can be arranged to be spaced apart from each other while the plurality of communication lines NL extending in the row direction are disposed therebetween. Accordingly, the number of the plurality of sub-pixels can be greater than the number of the plurality of second electrodes CE2. In another example, all of the second electrodes CE2 of the plurality of sub-pixels can be connected to each other, such that only one second electrode CE2 can be disposed on the substrate 110. However, example embodiments of the present disclosure are not limited thereto.

Each of the plurality of second electrodes CE2 can be made of a transparent conductive material. However, example embodiments of the present disclosure are not limited thereto. Each of the plurality of second electrodes CE2 can be made of a transparent conductive material, and can allow light emitted from the light-emitting element ED to be directed upwardly of the second electrode CE2. For example, the second electrode CE2 can be made of a transparent conductive material such as Indium Tin Oxide (ITO), Indium Zinc Oxide (IZO), Indium Gallium Zinc Oxide (IGZO), etc. However, example embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap the plurality of contact electrodes CCE.

For example, each of the plurality of contact electrodes CCE can be electrically connected to each of the plurality of second electrodes CE2. Each of the plurality of contact electrodes CCE can be disposed between the substrate 110 and each of the plurality of second electrodes CE2 to transmit the cathode voltage from the pixel driving circuit PD to each of the second electrodes CE2.

For example, when the micro LED is used as the light-emitting element ED, a plurality of micro LEDs can be formed on a wafer, and the micro LEDs can be transferred to the substrate 110 of the display device 1000 to manufacture the display device 100. Various defects can occur in the process of transferring the plurality of light-emitting elements ED having a fine size from the wafer to the substrate 110. For example, a non-transfer defect in which the light-emitting element ED is not transferred can occur in some sub-pixels, and an incorrect position defect in which the light-emitting element ED is transferred out of the correct position due to an alignment error can occur in some further sub-pixels. In addition, the transfer process is normally performed, while the transferred light-emitting element ED itself can be defective. Therefore, the plurality of light-emitting elements ED of the same type can be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective can be used.

For example, both the (1-1)-th light-emitting element 130a and the (1-2)-th light-emitting element 130b can be transferred to one pixel PX at the same time, and whether they are defective can be inspected. When both the (1-1)-th light-emitting element 130a and the (1-2)-th light-emitting element 130b are determined to be normal or non-defective, only the (1-1)-th light-emitting element 130a can be used, and the (1-2)-th light-emitting element 130b may not be used. In another example, when only the (1-2)-th light-emitting element 130b among the (1-1)-th light-emitting element 130a and the (1-2)-th light-emitting element 130b is determined to be normal or non-defective, the (1-1)-th light-emitting element 130a may not be used and only the (1-2)-th light-emitting element 130b can be used. Therefore, even when the plurality of light-emitting elements ED of the same type are transferred to one pixel PX, only one light-emitting element ED can be finally used.

Accordingly, one of the pair of light-emitting elements ED can act as a main (primary) light-emitting element ED, and the other of the pair of light-emitting elements ED can act as a redundant light-emitting element ED. The redundant light-emitting element ED can be an extra light-emitting element ED that is transferred in preparation for the defect of the main light-emitting element ED. When the main light-emitting element ED is defective, the main light-emitting element ED can be replaced with the redundant light-emitting element ED. Accordingly, both the main light-emitting element ED and the redundant light-emitting element ED are transferred to one pixel PX at the same time, thereby minimizing a decrease in display quality due to the defect of the main light-emitting element ED and the redundant light-emitting element ED.

For example, each of the (1-1)-th light-emitting element 130a, the (2-1)-th light-emitting element 140a, and the (3-1)-th light-emitting element 150a transferred to one pixel PX can be used as the main light-emitting element ED, while each of the (1-2)-th light-emitting element 130b, the (2-2)-th light-emitting element 140b, and the (3-2)-th light-emitting element 150b can be used as the redundant light-emitting element ED, but not limited thereto.

FIG. 8 is a cross-sectional view of a display device according to an example embodiment of the present disclosure. FIG. 9 is a cross-sectional view of a display device according to an example embodiment of the present disclosure. For example, FIG. 8 is a cross-sectional view of the display area AA, the first non-display area NA1, the bending area BA, and the second non-display area NA2. For example, FIG. 9 is a cross-sectional view of a display area including one sub-pixel SP1.

Referring to FIG. 8, a first buffer layer 111a and a second buffer layer 111b can be disposed on the remaining area of the substrate 110 except for the bending area BA.

The first buffer layer 111a and the second buffer layer 111b can be disposed in the display area AA, the first non-display area NA1, and the second non-display area NA2. The first buffer layer 111a and the second buffer layer 111b can prevent or reduce invasion of moisture or impurities through the substrate 110. Each of the first buffer layer 111a and the second buffer layer 111b can be made of an inorganic insulating material. For example, each of the first buffer layer 111a and the second buffer layer 111b can be formed as a single layer or multiple layers made of silicon oxide (SiOx) or silicon nitride (SiNx). For example, the first buffer layer 111a and the second buffer layer 111b can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. The first buffer layer 111a and the second buffer layer 111b can be excluded in accordance with the structure or properties of the display device. However, example embodiments of the present disclosure are not limited thereto.

For example, a portion of each of the first buffer layer 111a and the second buffer layer 111b in the bending area BA can be removed. An upper surface of a portion of the substrate 110 located in the bending area BA can be not covered with the first buffer layer 111a and the second buffer layer 111b so as to be exposed. Removing the portion of each of the first buffer layer 111a and the second buffer layer 111b made of the inorganic insulating material as disposed in the bending area BA can allow cracks of the first buffer layer 111a and the second buffer layer 111b that can occur during bending to be minimized.

A plurality of alignment keys MK can be disposed between the first buffer layer 111a and the second buffer layer 111b. The plurality of alignment keys MK can be configured to identify the position of the pixel driving circuit PD during the manufacturing process of the display device 1000. For example, the plurality of alignment keys MK can be configured to correctly align the positions of the pixel driving circuits PD transferred onto the adhesive layer 112. In another example, the plurality of alignment keys MK can be omitted, but not limited thereto.

The adhesive layer 112 can be disposed on the second buffer layer 111b. The adhesive layer 112 can be disposed in the display area AA, the first non-display area NA1, the bending area BA, and the second non-display area NA2. In another example, at least a portion of the adhesive layer 112 can be removed in the non-display area NA including the bending area BA. For example, the adhesive layer 112 can be made of one of an adhesive polymer, an epoxy resin, a UV curable resin, a polyimide-based resin, an acrylate-based resin, a urethane-based resin, and polydimethylsiloxane (PDMS). However, example embodiments of the present disclosure are not limited thereto.

The pixel driving circuit PD can be disposed on the adhesive layer 112 and in the display area AA. When the pixel driving circuit PD is implemented as a driver, the driver can be mounted on the adhesive layer 112 in a transfer process. However, example embodiments of the present disclosure are not limited thereto.

A first protective layer 113a and a second protective layer 113b can be disposed on the adhesive layer 112 and the pixel driving circuit PD. The first protective layer 113a and the second protective layer 113b can be disposed to surround a side surface of the pixel driving circuit PD. However, example embodiments of the present disclosure are not limited thereto. For example, the second protective layer 113b can be disposed to cover at least a portion of an upper surface of the pixel driving circuit PD. For example, at least one of the first protective layer 113a and the second protective layer 113b disposed on the bending area BA can be omitted. For example, the first protective layer 113a can be entirely disposed in the display area AA and the non-display area NA, and the second protective layer 113b can be partially disposed in the display area AA, the first non-display area NA1, and the second non-display area NA2. For example, a portion of the second protective layer 113b in the bending area BA can be removed. However, example embodiments of the present disclosure are not limited thereto.

Each of the first protective layer 113a and the second protective layer 113b can be made of an organic insulating material. However, example embodiments of the present disclosure are not limited thereto. For example, each of the first protective layer 113a and the second protective layer 113b can be made of a photoresist, polyimide (PI), or a photo acryl-based material. However, example embodiments of the present disclosure are not limited thereto. For example, each of the first protective layer 113a and the second protective layer 113b can be embodied as an overcoat layer or an insulating layer. However, example embodiments of the present disclosure are not limited thereto.

According to the present disclosure, a plurality of first connection lines 121 can be disposed on the second protective layer 113b and in the display area AA. The plurality of first connection lines 121 can be lines for electrically connecting the pixel driving circuit PD to other components. For example, the pixel driving circuit PD can be electrically connected to the plurality of signal lines TL and the plurality of contact electrodes CCE via the plurality of first connection lines 121. For example, the plurality of first connection lines 121 can include a (1-1)-th connection line 121a, a (1-2)-th connection line 121b, a (1-3)-th connection line 121c, and a (1-4)-th connection line 121d. However, example embodiments of the present disclosure are not limited thereto.

For example, a plurality of (1-1)-th connection lines 121a can be disposed on the second protective layer 113b. The plurality of (1-1)-th connection lines 121a can be electrically connected to the pixel driving circuit PD. The plurality of (1-1)-th connection lines 121a can transmit a voltage output from the pixel driving circuit PD to the first electrode CE1 or the second electrode CE2.

For example, a third protective layer 114 can be disposed on the second protective layer 113b. The protective layer 114 can be entirely disposed in the display area AA and the non-display area NA. In the bending area BA, the third protective layer 114 can cover a side surface of the second protective layer 113b and an upper surface of the first protective layer 113a. The third protective layer 114 can be made of an organic insulating material. For example, the third protective layer 114 can be made of a photoresist, polyimide (PI), or a photo acryl-based material. However, example embodiments of the present disclosure are not limited thereto. For example, the first protective layer 113a, the second protective layer 113b, and the third protective layer 114 can be made of the same material. Example embodiments of the present disclosure are not limited thereto.

A plurality of (1-2)-th connection lines 121b can be disposed on the third protective layer 114. The plurality of (1-2)-th connection lines 121b can be indirectly connected to the pixel driving circuit PD or can be directly connected thereto. For example, some of the (1-2)-th connection lines 121b can be directly connected to the pixel driving circuit PD via a contact hole of the third protective layer 114. The others of the (1-2)-th connection line 121b can be electrically connected to the (1-1)-th connection line 121a via a contact hole of the third protective layer 114. However, example embodiments of the present disclosure are not limited thereto. The voltage output from the pixel driving circuit PD can be transmitted to the first electrode CE1 or the second electrode CE2 via a connection line different from the plurality of (1-2)-th connection lines 121b.

A first insulating layer 115a can be disposed on the plurality of (1-2)-th connection lines 121a. The first insulating layer 115a can be entirely disposed in the display area AA and the non-display area NA. However, example embodiments of the present disclosure are not limited thereto. The first insulating layer 115a can be made of an organic insulating material. However, example embodiments of the present disclosure are not limited thereto. For example, the first insulating layer 115a can be made of a photo resist, polyimide (PI), or a photo acryl-based material. However, example embodiments of the present disclosure are not limited thereto.

A plurality of (1-3)-th connection lines 121c can be disposed on the first insulating layer 115a. The plurality of (1-3)-th connection lines 121c can be electrically connected to the plurality of (1-2)-th connection lines 121b, respectively. For example, the (1-3)-th connection line 121c can be electrically connected to the (1-2)-th connection line 121a via a contact hole of the first insulating layer 115a.

A second insulating layer 115b can be disposed on the plurality of (1-3)-th connection lines 121b. The second insulating layer 115b can be disposed in the remaining area except for the bending area BA. However, example embodiments of the present disclosure are not limited thereto. The second insulating layer 115b can be disposed in the display area AA, the first non-display area NA1, and the second non-display area NA2. However, example embodiments of the present disclosure are not limited thereto. For example, a portion of the second insulating layer 115b disposed in the bending area BA can be removed. The second insulating layer 115b can be made of an organic insulating material. However, example embodiments of the present disclosure are not limited thereto. For example, the second insulating layer 115b can be made of a photo resist, polyimide (PI), or a photo acryl-based material. However, example embodiments of the present disclosure are not limited thereto.

A plurality of (1-4)-th connection lines 121d can be disposed on the second insulating layer 115b. The plurality of (1-4)-th connection lines 121d can be electrically connected to the plurality of (1-3)-th connection lines 121c, respectively. For example, the (1-4)-th connection line 121d can be electrically connected to the (1-3)-th connection line 121b via a contact hole of the second insulating layer 115b.

According to the present disclosure, a plurality of second connection lines 122 can be disposed on the second protective layer 113b and in the non-display area NA. The plurality of second connection lines 122 can be lines for transmitting signals transmitted from the flexible circuit board 157 and the printed circuit board 160 (see FIG. 1) to the pad PAD to the pixel driving circuit PD of the display area AA. For example, the plurality of second connection lines 122 can be electrically connected to the plurality of pad electrodes PE respectively to receive signals from the flexible circuit board (or flexible film) 157 and the printed circuit board.

For example, the plurality of second connection lines 122 can extend from the pad PAD toward the display area AA to transmit signals to the lines of the display area AA. In this case, the plurality of second connection lines 122 can function as link lines LL. The plurality of second connection lines 122 can include a (2-1)-th connection line 122a, a (2-2)-th connection line 122b, a (2-3)-th connection line 122c, and a (2-4)-th connection line 122d.

A plurality of (2-1)-th connection lines 122a can be disposed on the second protective layer 113a. The plurality of (2-1)-th connection lines 122a can extend from the second non-display area NA2 to the bending area BA and the first non-display area NA1. The plurality of (2-1)-th connection lines 122a can transmit signals transmitted from the flexible circuit board (or flexible film) 157 and the printed circuit board to the pad PAD to the pixel driving circuit PD of the display area AA. For example, the (2-1)-th connection line 122a can be electrically connected to the pixel driving circuit PD via the first connection line 121 of the display area AA. The (2-1)-th connection line 122a can be electrically connected to the second electrode CE2 via the first connection line 121 and the contact electrode CCE of the display area AA.

A plurality of (2-2)-th connection lines 122b can be disposed on the third protective layer 114. The plurality of (2-2)-th connection lines 122b can be disposed in the second non-display area NA2. The (2-2)-th connection line 122b can be electrically connected to the (2-1)-th connection line 122a via a contact hole of the third protective layer 114. Accordingly, signals from the flexible circuit board (or flexible film) 157 and the printed circuit board can be transmitted to the (2-1)-th connection line 122b via the (2-1)-th connection line 122a.

The (2-3)-th connection line 122c can be disposed on the first insulating layer 115a. The (2-3)-th connection line 122c can be disposed in the second non-display area NA2. The (2-3)-th connection line 122c can be electrically connected to the (2-2)-th connection line 122a via a contact hole of the first insulating layer 115a. Accordingly, signals from the flexible circuit board (or flexible film) 157 and the printed circuit board can be transmitted to the (2-1)-th connection line 122a via the (2-3)-th connection line 122c and the (2-2)-th connection line 122b.

The (2-4)-th connection line 122d can be disposed on the second insulating layer 115b. The (2-4)-th connection line 122d can be disposed in the second non-display area NA2. The (2-4)-th connection line 122d can be electrically connected to the (2-3)-th connection line 122b via a contact hole of the second organic insulating layer 115c. Accordingly, signals from the flexible film FF and the printed circuit board can be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 can be made of a conductive material having excellent ductility or various conductive materials used in the display area AA. For example, the second connection line 122, a portion of which is disposed in the bending area BA, can be made of a conductive material having excellent ductility, such as gold (Au), silver (Ag), or aluminum (Al). However, example embodiments of the present disclosure are not limited thereto. In another example, each of the plurality of first connection lines 121 and the plurality of second connection lines 122 can be made of molybdenum (Mo), chromium (Cr), titanium (Ti), nickel (Ni), neodymium (Nd), copper (Cu), an alloy thereof, or an alloy of silver (Ag) and magnesium (Mg). However, example embodiments of the present disclosure are not limited thereto.

A third insulating layer 115c can be disposed on the plurality of first connection lines 121 and the plurality of second connection lines 122. The third insulating layer 115c can be disposed in the remaining area except for the bending area BA. However, example embodiments of the present disclosure are not limited thereto. The third insulating layer 115c can be disposed in the display area AA, the first non-display area NA1, and the second non-display area NA2. A portion of the third insulating layer 115c in the bending area BA can be removed. The third insulating layer 115c can be made of an organic insulating material. However, example embodiments of the present disclosure are not limited thereto. For example, the third insulating layer 115c can be made of a photo resist, polyimide (PI), or a photo acryl-based material. However, example embodiments of the present disclosure are not limited thereto.

In the display area AA, a plurality of banks BNK can be disposed on the third insulating layer 115c. The plurality of banks BNK can be disposed to overlap the plurality of sub-pixels, respectively. One or more light-emitting elements ED of the same type can be disposed on each of the plurality of banks BNK.

In the display area AA, the plurality of signal lines TL can be disposed on the third insulating layer 115c. The plurality of signal lines TL can be disposed in an area between adjacent ones of the plurality of banks BNK. For example, the plurality of signal lines TL can be disposed adjacent to one of the plurality of banks BNK.

The plurality of contact electrodes CCE can be disposed on the third insulating layer 115c in the display area AA. The plurality of contact electrodes CCE can supply the cathode voltage from the pixel driving circuit PD to the second electrode CE2.

The first electrode CE1 can be disposed on the bank BNK. For example, the first electrode CE1 can be disposed to extend from the adjacent signal line TL toward the top of the bank BNK. The first electrode CE1 can be disposed on an upper surface of the bank BNK and a side surface of the bank BNK. For example, the first electrode CE1 can be disposed to extend from the signal line TL on the upper surface of the third insulating layer 115c to the side surface of the bank BNK and the upper surface of the bank BNK.

Referring to FIG. 9, the first electrode CE1 can be made of a plurality of conductive layers. For example, the first electrode CE1 can include a first conductive layer CE1a, a second conductive layer CE1b, a third conductive layer CE1c, and a fourth conductive layer CE1d. However, example embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, each of the first conductive layer CE1a, the second conductive layer CE1b, the third conductive layer CE1c, and the fourth conductive layer CE1d can be made of titanium (Ti), molybdenum (Mo), aluminum (Al), titanium (Ti) or indium tin oxides (ITO). However, example embodiments of the present disclosure are not limited thereto.

According to the present disclosure, some conductive layers having good reflection efficiency among the plurality of conductive layers constituting the first electrode CE1 can act as an alignment key for aligning the light-emitting element ED and/or a reflective plate. For example, the second conductive layer CE1b of the plurality of conductive layers of the first electrode CE1 can include a reflective material. For example, the second conductive layer CE1b can include aluminum (Al). However, example embodiments of the present disclosure are not limited thereto. Accordingly, the second conductive layer CE1b can act as the reflective plate. In addition, due to the high reflection efficiency of the second conductive layer CE1b, the second conductive layer CE1b can be easily identified in the manufacturing process, and thus the position of the light-emitting element ED or the transfer position can be aligned with the second conductive layer CE1b.

For example, in order that the second conductive layer CE1b acts as the reflective plate, a portion of each of the third conductive layer CE1c and the fourth conductive layer CE1d covering the second conductive layer CE1b can be removed or etched. For example, an upper surface of the second conductive layer CE1b can be exposed by removing or etching the portion of each of the third conductive layer CE1c and the fourth conductive layer CE1d disposed on the bank BNK. For example, a central portion and an edge portion (or a rim portion) of each of the third conductive layer CE1c and the fourth conductive layer CE1d, on which a solder pattern SDP is disposed, can be left, and the remaining portion other than the central portion and the edge portion thereof can be removed. For example, the edge portion (or the rim portion) of each of the third conductive layer CE1c made of titanium (Ti) and the fourth conductive layer CE1d made of indium tin oxide (ITO) may not be etched. This can prevent the other conductive layers of the first electrode CE1 from being corroded by a tetraMethylammoniumhydroxide (TMAH) solution used in a mask process of the first electrode CE1.

According to the present disclosure, each of the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer such as indium tin oxide (ITO) or indium zinc oxide (IZO), which has good adhesion to the solder pattern SDP and has corrosion resistance and acid resistance. However, example embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process thereon. However, example embodiments of the present disclosure are not limited thereto.

According to the present disclosure, each of the signal line TL, the contact electrode CCE, and the pad electrode PE which are disposed at the same layer as a layer of the first electrode CE1, can be composed of multiple layers of a conductive material. However, example embodiments of the present disclosure are not limited thereto. For example, each of the signal line TL, the contact electrode CCE, and the pad electrode PE can be composed of a multi-layers structure of indium tin oxide (Indium Tin Oxide, ITO) layer/titanium (Ti) layer/aluminum (Al) layer/titanium (Ti) layer. However, example embodiments of the present disclosure are not limited thereto.

According to the present disclosure, the solder pattern SDP can be disposed on the first electrode CE1 and in each of the plurality of sub-pixels. The solder pattern SDP can bond the light-emitting element ED to the first electrode CE1. The first electrode CE1 and the light-emitting element ED can be electrically connected to each other by eutectic bonding using by melting of the solder pattern SDP. However, example embodiments of the present disclosure are not limited thereto. For example, when the solder pattern SDP is made of indium (In) and the anode electrode 134 of the light-emitting element ED is made of gold (Au), heat and pressure can be applied thereto in the transfer process of the light-emitting element ED to bond the solder pattern SDP and the anode electrode 134 to each other. By the eutectic bonding, the light-emitting element ED can be bonded to the solder pattern SDP and the first electrode CE1 without a separate adhesive. For example, the solder pattern SDP can be made of indium (In), tin (Sn), or an alloy thereof. However, example embodiments of the present disclosure are not limited thereto. For example, the solder pattern SDP can be embodied as a bonding pad, etc. However, example embodiments of the present disclosure are not limited thereto.

According to the present disclosure, a passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE in the second non-display area NA2 can be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED can be reduced. For example, the passivation layer 116 can be formed as a single layer or multiple layers made of silicon oxide (SiOx) or silicon nitride (SiNx). For example, the passivation layer 116 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si). However, example embodiments of the present disclosure are not limited thereto. For example, the passivation layer 116 can be embodied as a protective layer, an insulating layer, etc. However, example embodiments of the present disclosure are not limited thereto. For example, the passivation layer 116 can have a hole defined therein exposing the solder pattern SDP.

In each of the plurality of sub-pixels, the light-emitting element ED can be disposed on the solder pattern SDP. The first light-emitting element 130 can be disposed in the first sub-pixel SP1. The second light-emitting element 140 can be disposed in the second sub-pixel SP2. The third light-emitting element 150 can be disposed in the third sub-pixel SP3. Each of the plurality of light-emitting elements 130, 140, and 150 can be embodied as a micro light-emitting element.

The light-emitting element ED can be formed on a silicon wafer using an Metal Organic Chemical Vapor Deposition (MOCVD) method, a Chemical Vapor Deposition (CVD) method, a Plasma-Enhanced Chemical Vapor Deposition (PECVD) method, a Molecular Beam Epitaxy (MBE) method, a Hydride Vapor Phase Epitaxy (HVPE) method, or sputtering method. However, example embodiments of the present disclosure are not limited thereto.

Referring to FIG. 9, the first light-emitting element 130 can include an anode electrode 134, a first semiconductor layer 131, an active layer 132, a second semiconductor layer 133, a cathode electrode 135, and an encapsulation film 136. However, example embodiments of the present disclosure are not limited thereto. For example, the encapsulation film 136 may not be included in the first light-emitting element 130.

The anode electrode 134 can be disposed on the solder pattern SDP. The first semiconductor layer 131 can be disposed on the anode electrode 134. The active layer 132 can be disposed on the first semiconductor layer 131. The second semiconductor layer 133 can be disposed on the active layer 132.

For example, one of the first semiconductor layer 131 and the second semiconductor layer 133 can be made of a compound semiconductor such as a group III-V, a group II-VI, or the like, and can be doped with impurities (or dopants). For example, one of the first semiconductor layer 131 and the second semiconductor layer 133 can be a semiconductor layer doped with n-type impurities, and the other thereof can be a semiconductor layer doped with p-type impurities. However, example embodiments of the present disclosure are not limited thereto. For example, at least one of the first semiconductor layer 131 and the second semiconductor layer 133 can be a layer in which n-type or p-type impurities are doped in a material such as gallium nitride (GaN), gallium phosphide (GaP), gallium arsenide (GaAsP), aluminum gallium indium phosphide (AlGalnP), indium aluminum phosphide (InAlP), aluminum gallium nitride (AlGaN), aluminum indium gallium nitride (AlInN), aluminum gallium arsenide (AlGaAs), or gallium arsenide (GaAs). However, example embodiments of the present disclosure are not limited thereto. For example, the n-type impurity can include silicon (Si), germanium (Ge), selenium (Se), carbon (C), tellurium (Te), tin (Sn), etc. However, example embodiments of the present disclosure are not limited thereto. For example, the p-type impurity can include magnesium (Mg), zinc (Zn), calcium (Ca), strontium (Sr), barium (Ba), beryllium (Be), etc. However, example embodiments of the present disclosure are not limited thereto.

For example, each of the first semiconductor layer 131 and the second semiconductor layer 133 can be made of a nitride semiconductor including n-type impurities and a nitride semiconductor including p-type impurities. However, example embodiments of the present disclosure are not limited thereto. For example, the first semiconductor layer 131 can be made of a nitride semiconductor including p-type impurities, and the second semiconductor layer 133 can be made of a nitride semiconductor including n-type impurities. However, example embodiments of the present disclosure are not limited thereto.

The active layer 132 can be disposed between the first semiconductor layer 131 and the second semiconductor layer 133. The active layer 132 can receive holes and electrons from the first semiconductor layer 131 and the second semiconductor layer 133 to emit light. For example, the active layer 132 can be composed of one of a single well structure, a multiple well structure, a single quantum well structure, a multi-quantum well (MQW) structure, a quantum dot structure, and a quantum wire structure. However, example embodiments of the present disclosure are not limited thereto. For example, the active layer 132 can be made of indium gallium nitride (InGaN) or gallium nitride (GaN). However, example embodiments of the present disclosure are not limited thereto.

In another example, the active layer 132 can include a MQW (Multi Quantum Well) structure having a well layer and a barrier layer having a higher band gap than that of the well layer. For example, the active layer 132 can include InGaN as a material of the well layer and AlGaN as a material of the barrier layer. However, example embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1 to each other. The anode voltage output from the pixel driving circuit PD can be applied to the first semiconductor layer 131 via the signal line TL, the first electrode CE1, and the anode electrode 134. For example, the anode electrode 134 can be made of a conductive material capable of eutectic bonding with the solder pattern SDP. However, example embodiments of the present disclosure are not limited thereto. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, example embodiments of the present disclosure are not limited thereto.

The cathode electrode 135 can be disposed on the second semiconductor layer 133. For example, the cathode electrode 135 can electrically connect the second semiconductor layer 133 and the second electrode CE2 to each other. The cathode voltage output from the pixel driving circuit PD can be applied to the second semiconductor layer 133 via the contact electrode CCE, the second electrode CE2, and the cathode electrode 135. The cathode electrode 135 can be made of a transparent conductive material so that light emitted from the light-emitting element ED can be directed upwardly of the light-emitting element ED. However, example embodiments of the present disclosure are not limited thereto. For example, the cathode electrode 135 can be made of a material such as Indium Tin Oxide (ITO), Indium Zinc Oxide (IZO), or Indium Gallium Zinc Oxide (IGZO). However, example embodiments of the present disclosure are not limited thereto.

The encapsulation film 136 can be disposed on at least a portion of each of the first semiconductor layer 131, the active layer 132, the second semiconductor layer 133, the anode electrode 134, and the cathode electrode 135. For example, the encapsulation film 136 can surround at least a portion of each of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least a portion of each of the anode electrode 134 and the cathode electrode 135, for example, an edge portion (or one side surface) of the anode electrode 134 and an edge portion (or one side surface) of the cathode electrode 135. At least a portion of the anode electrode 134 may not be covered with the encapsulation film 136 such that the anode electrode 134 and the solder pattern SDP are connected to each other. For example, at least a portion of the cathode electrode 135 may not be covered with the encapsulation film 136 such that the cathode electrode 135 and the second electrode CE2 are connected to each other. For example, the encapsulation film 136 can be made of an insulating material such as silicon nitride (SiNx) or silicon oxide (SiOx). For example, the encapsulation film 136 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si). However, example embodiments of the present disclosure are not limited thereto.

In another example, the encapsulation film 136 can have a structure in which a reflective material is dispersed in a resin layer. However, example embodiments of the present disclosure are not limited thereto. For example, the encapsulation film 136 can be embodied as a reflector having various structures. However, example embodiments of the present disclosure are not limited thereto. Light emitted from the active layer 132 can be reflected upwardly from the encapsulation film 136, thereby improving light extraction efficiency. For example, the encapsulation film 136 can be a reflective layer. However, example embodiments of the present disclosure are not limited thereto.

According to the present disclosure, an example in which the light-emitting element ED has a vertical structure has been described. However, example embodiments of the present disclosure are not limited thereto. For example, the light-emitting element ED can have a lateral structure or a flip chip structure.

Although the first light-emitting element 130 has been described with reference to FIG. 9, each of the second light-emitting element 140 and the third light-emitting element 150 can have substantially the same structure as that of the first light-emitting element 130. For example, the first semiconductor layer, the active layer, the second semiconductor layer, the anode electrode, the cathode electrode, and the encapsulation film of each of the second light-emitting element 140 and the third light-emitting element 150 can be substantially the same as the first semiconductor layer 131, the active layer 132, the second semiconductor layer 133, the anode electrode 134, the cathode electrode 135, and the encapsulation film 136 of the first light-emitting element 130, respectively.

The optical insulating layer 117 can include a first optical layer 117a, a second optical layer 117b, and a third optical layer 117c.

According to the present disclosure, the first optical layer 117a surrounding the plurality of light-emitting elements ED can be disposed in the display area AA. For example, the first optical layer 117a can be disposed to cover the plurality of light-emitting elements ED and the bank BNK in the areas of the plurality of sub-pixels. For example, the first optical layer 117a can cover the bank BNK, a portion of the passivation layer 116, and an area between adjacent ones of the plurality of light-emitting elements ED. The first optical layer 117a can be disposed in or cover an area between adjacent ones of the plurality of light-emitting elements ED included and an area between adjacent ones of the plurality of banks BNK in one pixel PX. For example, the first optical layer 117a can extend in the first direction X and the first optical layers 117a can be spaced apart from each other in the second direction Y. For example, the first optical layer 117a can be disposed between the passivation layer 116 and the second electrode CE2 so as to surround the side of each of the light-emitting element ED and the bank BNK. However, example embodiments of the present disclosure are not limited thereto. For example, the first optical layer 117a can act as a diffusion layer, a sidewall diffusion layer, etc. However, example embodiments of the present disclosure are not limited thereto.

The first optical layer 117a can include an organic insulating material in which fine particles are dispersed. However, example embodiments of the present disclosure are not limited thereto. For example, the first optical layer 117a can be made of siloxane in which fine metal particles such as titanium dioxide (TiO₂) particles are dispersed. However, example embodiments of the present disclosure are not limited thereto. Light from the plurality of light-emitting elements ED can be scattered by the fine particles dispersed in the first optical layer 117a and then emitted out of the display device 1000. Accordingly, the first optical layer 117a can improve extraction efficiency of light emitted from the plurality of light-emitting elements ED.

For example, the first optical layer 117a can be disposed in each of the plurality of pixels PX, or can be commonly disposed in some pixels PX arranged in the same row. However, example embodiments of the present disclosure are not limited thereto. For example, the first optical layer 117a can be disposed in each of the plurality of pixels PX, or the plurality of pixels PX can share one first optical layer 117a with each other. In another example, each of the plurality of sub-pixels SP can separately include the first optical layer 117a. However, example embodiments of the present disclosure are not limited thereto.

According to the present disclosure, the second optical layer 117b can be disposed on the passivation layer 116 and in the display area AA. For example, the second optical layer 117b can be disposed to surround the first optical layer 117a. For example, the second optical layer 117b can be in contact with a side surface of the first optical layer 117a. For example, the second optical layer 117b can be disposed in an area between adjacent ones of the plurality of pixels PX. However, example embodiments of the present disclosure are not limited thereto. For example, the second optical layer 117b can act as a diffusion layer, a diffusion layer window, a window diffusion layer, etc. However, example embodiments of the present disclosure are not limited thereto.

The second optical layer 117b can be made of an organic insulating material. However, example embodiments of the present disclosure are not limited thereto. The second optical layer 117b can be made of the same material as that of the first optical layer 117a. For example, the second optical layer 117b can be made of siloxane in which fine metal particles such as titanium dioxide (TiO₂) particles are dispersed. However, example embodiments of the present disclosure are not limited thereto. For example, the first optical layer 117a can include fine particles, and the second optical layer 117b may not include fine particles. For example, the second optical layer 117b can be made of siloxane. However, example embodiments of the present disclosure are not limited thereto.

For example, a thickness of the first optical layer 117a can be smaller than a thickness of the second optical layer 117b. However, example embodiments of the present disclosure are not limited thereto. Accordingly, in a cross-sectional view of the device, an area in which the first optical layer 117a is disposed can include a concave portion recessed downwardly beyond an upper surface of the second optical layer 117b.

According to the present disclosure, the second electrode CE2 can be disposed on the first optical layer 117a and the second optical layer 117b. For example, the second electrode CE2 can be electrically connected to the plurality of contact electrodes CCE via a contact hole of the second optical layer 117 b. For example, the second electrode CE2 can be disposed on the plurality of light-emitting elements ED. For example, the second electrode CE2 can include a transparent conductive oxide such as indium tin oxide (ITO) or indium zinc oxide (IZO). However, example embodiments of the present disclosure are not limited thereto. For example, the second electrode CE2 can be disposed to be in contact with the cathode electrode 135. For example, the second electrode CE2 can overlap the first optical layer 117a. For example, the second electrode CE2 can cover a flat upper surface of an outer portion of the first optical layer 117a.

The second electrode CE2 can continuously extend in the first direction of the substrate 110. Accordingly, the plurality of pixels PX arranged in the first direction of the substrate 110 can be commonly connected to the second electrode CE2. For example, the second electrode CE2 can be commonly connected to the plurality of pixels PX.

According to the present disclosure, the second electrode CE2 can continuously extend across the first optical layer 117a, the second optical layer 117b, and the plurality of light-emitting elements ED. An area in which the first optical layer 117a is disposed can include the concave portion recessed downwardly beyond the upper surface of the second optical layer 117b. Accordingly, since a first portion of the second electrode CE2 disposed on the first optical layer 117a is disposed along and on the concave portion, a vertical level of the first portion can be lower than a vertical level of a second portion of the second electrode CE2 disposed on the second optical layer 117b.

The third optical layer 117c can be disposed on the second electrode CE2. The third optical layer 117c can be disposed to overlap the plurality of light-emitting elements ED and the first optical layer 117a. Since the third optical layer 117c is disposed on the second electrode CE2 and the plurality of light-emitting elements ED, a mura that can occur in some of the plurality of light-emitting elements ED can be suppressed. For example, when the plurality of light-emitting elements ED are transferred onto the substrate 110 of the display device 100, an area in which spacings between adjacent ones of the plurality of light-emitting elements ED are not uniform can occur due to process variations or etc. When the spacings between adjacent ones of the plurality of light-emitting elements ED are non-uniform, respective light emission areas of the plurality of light-emitting elements ED can be non-uniformly arranged, and thus, the mura can be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user can be suppressed. Accordingly, the light emitted from the plurality of light-emitting elements ED can be uniformly diffused by the third optical layer 117c and then be extracted out of the display device 1000, such that the luminance uniformity of the display device 1000 can be improved.

The third optical layer 117c can be made of an organic insulating material in which fine particles are dispersed. However, an example embodiment of the present disclosure is not limited thereto. For example, the third optical layer 117c can be made of siloxane in which fine metal particles such as titanium dioxide (TiO₂) particles are dispersed. However, example embodiments of the present disclosure are not limited thereto. For example, the third optical layer 117c can be made of the same material as that of the first optical layer 117a. However, example embodiments of the present disclosure are not limited thereto. For example, the third optical layer 117c can act as a diffusion layer, an upper surface diffusion layer, etc. However, example embodiments of the present disclosure are not limited thereto.

According to the present disclosure, light from the plurality of light-emitting elements ED can be scattered by the fine particles dispersed in the third optical layer 117c and be emitted out of the display device 1000. The third optical layer 117c can evenly mix light beams respectively emitted from the plurality of light-emitting elements ED with each other to further improve luminance uniformity of the display device 1000. In addition, light extraction efficiency of the display device 1000 can be improved by the light being scattered from the plurality of fine particles, and accordingly, the display device 1000 can operate at a low power level.

A black matrix BM can be disposed on the second electrode CE2, the first optical layer 117a, the second optical layer 117b, and the third optical layer 117c and in the display area AA. For example, the black matrix BM can fill a contact hole of the second optical layer 117b. Since the black matrix BM is constructed to cover the display area AA, the black matrix can reduce color mixing between light beams from the plurality of sub-pixels and can prevent external light reflection. For example, since the black matrix BM is also disposed in the contact hole via which the second electrode CE2 and the contact electrode CCE are connected to each other, light leakage between adjacent ones of the plurality of sub-pixels can be prevented.

For example, the black matrix BM can be made of an opaque material. However, example embodiments of the present disclosure are not limited thereto. For example, the black matrix BM can be made of an organic insulating material to which a black pigment or a black dye is added. For example, the black matrix BM can be formed of an organic layer such as an acryl-based material, an epoxy-based material, a phenolic-based material, a polyamide-based material, or a polyimide-based material, to which a black pigment or a black dye is added. However, example embodiments of the present disclosure are not limited thereto.

A cover layer 118 can be disposed on the black matrix BM and in the display area AA. The cover layer 118 can protect the components under the cover layer 118. For example, the cover layer 118 can be made of an organic insulating material. However, example embodiments of the present disclosure are not limited thereto. For example, the cover layer 118 can be made of a photoresist, polyimide (PI), or a photo acryl-based material. However, example embodiments of the present disclosure are not limited thereto. For example, the cover layer 118 can be embodied as an overcoat layer, an insulating layer, etc. However, example embodiments of the present disclosure are not limited thereto.

The polarizing layer 293 can be disposed on the cover layer 118 via a first adhesive layer 291. The cover member 155 can be disposed on the polarizing layer 293 via a second adhesive layer 295. For example, each of the first adhesive layer 291 and the second adhesive layer 295 can include an OCA (Optically clear adhesive), an OCR (Optically clear resin), a PSA (Pressure sensitive adhesive), etc. However, example embodiments of the present disclosure are not limited thereto.

According to the present disclosure, the plurality of pad electrodes PE can be disposed on the third insulating layer 115c and in the second non-display area NA2. For example, at least a portion of each of the plurality of pad electrodes PE may not be covered with the passivation layer 116 so as to be exposed. For example, the plurality of pad electrodes PE can be electrically connected to the (2-4)-th connection line 122c via a contact hole of the third insulating layer 115d.

An adhesive layer ACF can be disposed on the plurality of pad electrodes PE. The adhesive layer ACF can be an adhesive layer in which conductive balls are dispersed in an insulating material. However, example embodiments of the present disclosure are not limited thereto. When heat or pressure is applied to the adhesive layer ACF, the conductive balls can be electrically connected to each other in an area to which the heat or pressure has been applied such that the adhesive layer ACF can be conductive. The adhesive layer ACF can be disposed between the plurality of pad electrodes PE and the flexible circuit board (or flexible film) 157 to attach or bond the flexible circuit board (or flexible film) 157 to the plurality of pad electrodes PE. For example, the adhesive layer ACF can be embodied as an anisotropic conductive film (ACF). However, example embodiments of the present disclosure are not limited thereto.

The flexible circuit board (or flexible film) 157 can be disposed on the adhesive layer ACF. The flexible circuit board (or flexible film) 157 can be electrically connected to the plurality of pad electrodes PE via the adhesive layer ACF. Accordingly, the signals output from the flexible circuit board (or flexible film) 157 and the printed circuit board can be transmitted to the pixel driving circuit PD of the display area AA via the plurality of pad electrodes PE, the (2-4)-th connection line 122d, the (2-3)-th connection line 122c, the (2-2)-th connection line 122b, and the (2-1)-th connection line 122a.

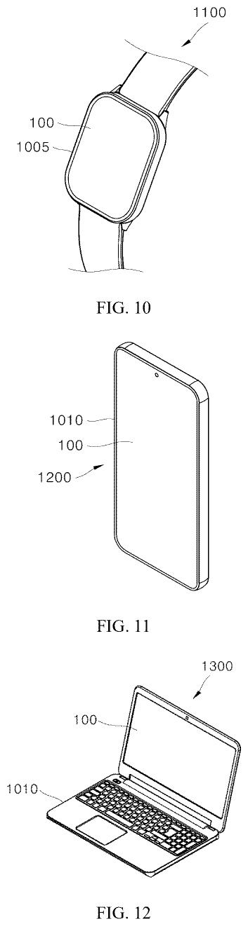

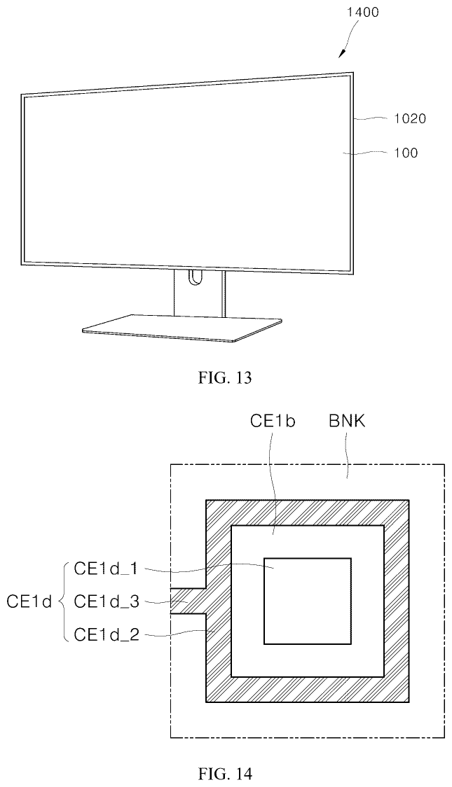

FIGS. 10 to 13 are diagrams illustrating an apparatus to which a display device according to example embodiments of the present disclosure is applied.

Referring to FIGS. 10 to 13, a display device 1000 according to example embodiments of the present disclosure can be included in various apparatus or electronic devices. For example, referring to FIGS. 10 to 13, various electronic devices can include a wearable device 1100, a mobile device 1200, a notebook computer 1300, and a monitor or TV 1400. However, example embodiments of the present disclosure are not limited thereto.

Each of the wearable device 1100, the mobile device 1200, the notebook computer 1300, and the monitor or TV 1400 can include a casing 1005, 1010, 1015, or 1020 and the display device 1000 including the display panel 100 and according to example embodiments of the present disclosure as described above with reference to FIGS. 1 to 9.

For example, the display device according to an example embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), a MP3 player, a mobile medical device, a desktop PC, a laptop PC, a netbook computer, a workstation, a navigation system, a vehicle display device, a theater display device, a television, a wall paper device, a signage device, a game device, a notebook computer, a monitor, a camera, a camcorder, a home appliance, etc.

FIG. 14 is a plan view illustrating a bonding area in FIG. 9.

Referring to FIGS. 9 and 14, a bonding pad CE1d_1 can be disposed on the first electrode CE1. The bonding pad CE1d_1 can be made of indium (In), tin (Sn), or an alloy thereof. However, example embodiments of the present disclosure are not limited thereto. For example, the bonding pad CE1d_1 can be the solder pattern SDP (see FIG. 9).

The bonding pad CE1d_1 can be connected to the anode electrode 134 of the light-emitting element 130. The light-emitting element 130 can be electrically connected to the first electrode CE1 via the bonding pad CE1d_1.

The first electrode CE1 can include a single layer or multiple layers made of one selected from titanium (Ti), molybdenum (Mo), and aluminum (Al). For example, the first electrode CE1 can include a multilayer structure including the first conductive layer CE1a, the second conductive layer CE1b, the third conductive layer CE1c, and the fourth conductive layer CE1d.

The first metal layer CE1a and the third metal layer CE1c can include titanium (Ti) or molybdenum (Mo). The fourth metal layer CE1d can be disposed on the third metal layer CE1c. The fourth metal layer CE1d can include a material that is easily adhered to the bonding pad CE1d_1 and is resistant to oxidation, so that metal corrosion is not easily performed. For example, the fourth metal layer CE1d can include a transparent conductive oxide such as ITO (Indium Tin Oxide) or IZO (Indium Zinc Oxide), but not limited thereto.

The second metal layer CE1b can be disposed between the first metal layer CE1a and the third metal layer CE1c. The second metal layer CE1b can include a reflective material. For example, the second metal layer CE1b can include aluminum (Al). However, example embodiments of the present disclosure are not limited thereto.

The second metal layer CE1b can be disposed to overlap a light-emitting area EA including the light-emitting element 130. The second metal layer CE1b can reflect light emitted from the light-emitting element 130 toward the light-emitting area EA, thereby increasing the light efficiency of the display device.

Each of the fourth metal layer CE1d and the third metal layer CE1c can be patterned such that a partial area of the second metal layer CE1b can be exposed. For example, referring to FIG. 14, the second metal layer CE1b can include a shape surrounding four side surfaces of the bonding pad CE1d_1 contacting the light-emitting element 130. The fourth metal layer CE1d can include a first pattern CE1d_2 surrounding an outer side of the second metal layer CE1b and a second pattern CE1d_3 extending to and on the bank BNK in a plan view. The second pattern CE1d_3 of the fourth metal layer CE1d can extend along one side surface of the bank BNK. The second pattern CE1d_3 of the fourth metal layer CE1d can be an extension portion of the first electrode CE1. However, example embodiments of the present disclosure are not limited thereto. For example, the extension portion of the first electrode CE1 can have a multilayer structure including the first metal layer CE1a, the second metal layer CE1b, the third metal layer CE1c, and the fourth metal layer CE1d, but not limited thereto.

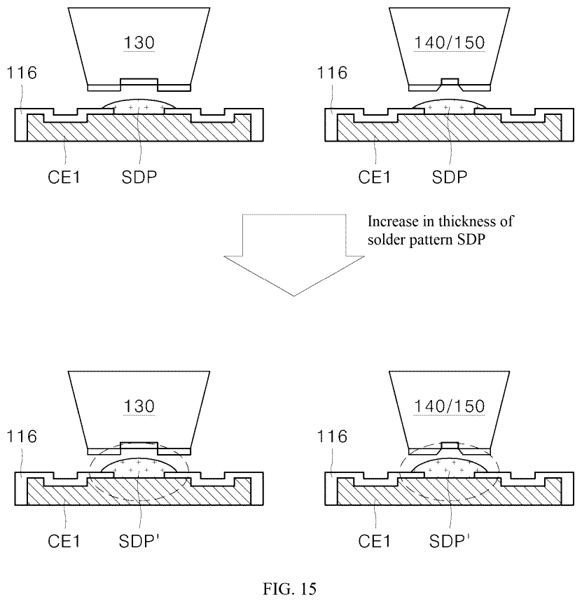

FIG. 15 is a cross-sectional view illustrating a display device according to a first example embodiment of the present disclosure.

Referring to FIGS. 8 and 15, in the display device according to the first example embodiment of the present disclosure, each of the light-emitting elements 130, 140, and 150 can be eutectically bonded to each of the first electrodes CE1 by each of the solder patterns SDP.

Each of the plurality of light-emitting elements 130, 140, and 150 can have a groove formed in a center of a bottom portion thereof. The solder pattern SDP can fill the groove and protrudes downwardly beyond a bottom surface of each of the plurality of light-emitting elements 130, 140, and 150, and thus the protruding portion thereof can be bonded to the first electrode CE1. Thus, each of the plurality of light-emitting elements 130, 140, and 150 can be electrically connected to each of the first electrodes CE1 via each of the solder patterns SDP.

In FIG. 15, a solder pattern SDP′ can have a thickness greater than a thickness of the lower electrode 134 of each of the light-emitting elements 130, 140, and 150.

In the first example embodiment of the present disclosure, the thickness of the solder pattern SDP′ for bonding each of the light-emitting elements 130, 140, and 150 to the first electrode CE1 is larger than that of the conventional solder pattern SDP.

In addition, the solder pattern SDP′ can have a thickness thinner than that of the first electrode CE1. For example, since the first electrode CE1 has a structure including the first metal layer CE1a, the second metal layer CE1b, the third metal layer CE1c, and the fourth metal layer CE1d, the first electrode CE1 can have a thickness greater than that of the solder pattern SDP′.

The passivation layer 116 can be disposed on the first electrode CE1. In this case, the solder pattern SDP′ can have a greater thickness than that of the passivation layer 116.

The solder pattern SDP′ can be made of indium (In), tin (Sn), or an alloy thereof, but not limited thereto.

In each of all of the plurality of light-emitting elements ED 130, 140, and 150, the solder pattern SDP′ can overlap the passivation layer 116.

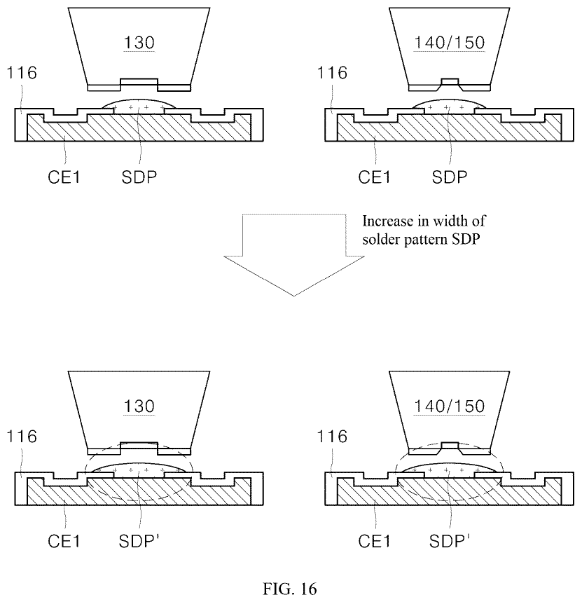

FIG. 16 is a cross-sectional view illustrating a display device according to a second example embodiment of the present disclosure.

Referring to FIGS. 8 and 16, in the display device according to the second example embodiment of the present disclosure, each of all of the light-emitting elements 130, 140, and 150 can have a width of an upper end greater than a width of a lower end.

In the second example embodiment of the present disclosure, a width (CD: Critical Dimension) of the solder pattern SDP′ for bonding each of the light-emitting elements 130, 140 and 150 to the first electrode CE1 is greater than that of the conventional solder pattern SDP. Accordingly, a bonding force between each of the light-emitting elements 130, 140, and 150 and the first electrode CE1 can be further increased.

The solder pattern SDP′ can have a width smaller than the width of the upper end of each of the light-emitting elements 130, 140, and 150.

The plurality of light-emitting elements ED can include the first light-emitting element 130 emitting red light, the second light-emitting element 140 emitting green light, and the third light-emitting element 150 emitting blue light. Each of the plurality of light-emitting elements 130, 140, and 150 can include one or more sub light-emitting element. For example, each of the plurality of light-emitting elements 130, 140, and 150 can include only one sub light-emitting element. For example, the first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b. However, the disclosure is not limited thereto. For example, the plurality of light-emitting elements ED can include a fourth light-emitting element emitting white light. The fourth light-emitting element can also include one or more sub light-emitting element.

The first light-emitting element 130 among the first light-emitting element 130, the second light-emitting element 140, and the third light-emitting element 150 can have the largest size (e.g., a volume). The second light-emitting element 140 and the third light-emitting element 150 can have the same size. For example, the size of second light-emitting element 140 and the size of the third light-emitting element 150 are same and are smaller than that of the first light-emitting element 130, but not limited thereto.

The solder pattern SDP′ can have a width equal to or smaller than a width of the lower end of the first light-emitting element 130, and can have a width greater than a width of the lower end of each of the second light-emitting element 140 and the third light-emitting element 150.

Each of the plurality of light-emitting elements 130, 140, and 150 can be embodied as a micro light-emitting element.

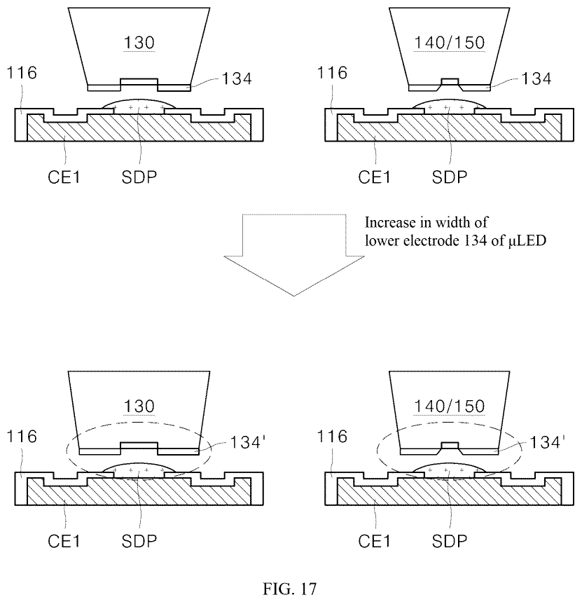

FIG. 17 is a cross-sectional view illustrating a display device according to a third example embodiment of the present disclosure.

Referring to FIGS. 8 and 17, in the display device according to the third example embodiment of the present disclosure, the lower electrode 134 bonded to the first electrode CE1 via the solder pattern SDP can be disposed in the lowest layer of each of the light-emitting elements 130, 140, and 150. In this regard, the lower electrode 134 can be the anode electrode 134.

According to the third example embodiment of the present disclosure, a width of the lower electrode 134 of each of the light-emitting elements 130, 140, and 150 bonded to the first electrode CE1 via the solder pattern SDP can be increased.

For example, as the width of the solder pattern SDP bonded to each of the light-emitting elements 130, 140, and 150 increases in the second example embodiment as described above, the width of the anode electrode 134 of each of the light-emitting elements 130, 140, and 150 is increased so as to correspond to the increased width of each solder pattern SDP in the third example embodiment of the present disclosure.

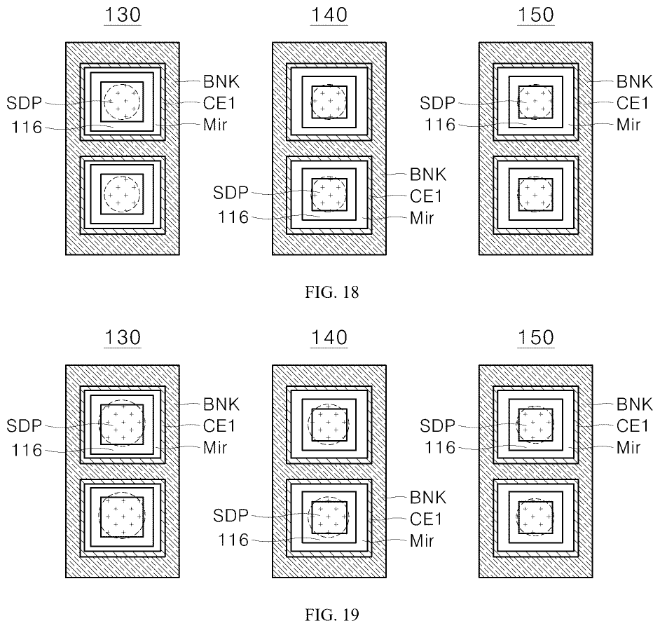

FIG. 18 is a plan view illustrating a display device according to the first example embodiment of the present disclosure.

Referring to FIG. 18, the display device according to the first example embodiment of the present disclosure can include the first light-emitting element 130, the second light-emitting element 140, and the third light-emitting element 150, each having a bonding area in which each of the main (primary) light-emitting element and the redundant light-emitting element is bonded to the first electrode CE1 in a top view.

Each of the first light-emitting element 130, the second light-emitting element 140, and the third light-emitting element 150 according to the first example embodiment of the present disclosure is in a state in which the thickness of each solder pattern SDP bonded thereto is further increased.

In the first light-emitting element 130, a main bonding area can be positioned in one of both opposing sides in the column direction, and a redundant bonding area can be positioned in the other of both opposing sides in the column direction, but not limited thereto.

In the second light-emitting element 140, a redundant bonding area can be located in one of both opposing sides in the column direction, and a main bonding area can be located in the other of both opposing sides in the column direction, but not limited thereto.

In the third light-emitting element 150, a main bonding area can be positioned in one of both opposing sides in the column direction, and a redundant bonding area can be positioned in the other of both opposing sides in the column direction, but not limited thereto.

Each solder pattern SDP can be disposed in the uppermost layer of each of the main bonding area and the redundant bonding area of each of the light-emitting elements 130, 140, and 150.

In the first example embodiment of the present disclosure, since the width of each solder pattern SDP is not increased but only the thickness thereof is increased, each solder pattern SDP in each of the light-emitting elements 130, 140, and 150 is disposed in each bonding area (square). For example, each solder pattern SDP can be disposed to contact each bonding area (square) or overlap each bonding area (square).

In each of the main bonding area and the redundant bonding area of each of the light-emitting elements 130, 140, and 150, the first electrode CE1 can be disposed on the bank BNK having the largest area, and the passivation layer 116 having a smaller area than that of the first electrode CE1 can be disposed thereon. The solder pattern SDP can be disposed on the passivation layer 116.

A mirror layer (or mirror portion) Mir can be disposed between the first electrode CE1 and the passivation layer 116. The fourth conductive layer CE1d is etched and removed in FIG. 14 to expose the second conductive layer CE1b made of the reflective material. Thus, the exposed portion of the second conductive layer CE1b made of the reflective material can act as the mirror layer Mir.

In each of all of the first light-emitting element 130, the second light-emitting element 140, and the third light-emitting element 150 according to the first example embodiment of the present disclosure, the solder pattern SDP can overlap the passivation layer 116 and may not overlap the mirror layer Mir.

Each of the first light-emitting element 130, the second light-emitting element 140, and the third light-emitting element 150 can have an upper end width greater than the width of each solder pattern SDP.

A lower end width of the first light-emitting element 130 can be greater than or equal to that of the solder pattern SDP, and a lower end width of each of the second and third light-emitting elements 140 and 150 can be smaller than that of each solder pattern SDP.

FIG. 19 is a plan view illustrating a display device according to the second example embodiment of the present disclosure.

Referring to FIG. 19, the display device according to the second example embodiment of the present disclosure can include the first light-emitting element 130, the second light-emitting element 140, and the third light-emitting element 150, each having a bonding area in which each of the main (primary) light-emitting element and the redundant light-emitting element is bonded to the first electrode CE1 in a top view.

Each of the first light-emitting element 130, the second light-emitting element 140, and the third light-emitting element 150 according to the second example embodiment of the present disclosure is in a state in which the width (CD) of each solder pattern SDP bonded thereto is further increased.

In the first light-emitting element 130, a main bonding area can be positioned in one of both opposing sides in the column direction, and a redundant bonding area can be positioned in the other of both opposing sides in the column direction, but not limited thereto.

In the second light-emitting element 140, a redundant bonding area can be located in one of both opposing sides in the column direction, and a main bonding area can be located in the other of both opposing sides in the column direction, but not limited thereto.

In the third light-emitting element 150, a main bonding area can be positioned in one of both opposing sides in the column direction, and a redundant bonding area can be positioned in the other of both opposing sides in the column direction, but not limited thereto.

In each of the main bonding area and the redundant bonding area of each of the light-emitting elements 130, 140, and 150, each solder pattern SDP can be disposed in the uppermost layer.

In the second example embodiment of the present disclosure, since the width of each solder pattern SDP is increased, each solder pattern SDP is positioned outwardly each bonding area (square) in each of the light-emitting elements 130, 140, and 150.

In each of the light-emitting elements 130, 140, and 150, the first electrode CE1 can be disposed on the bank BNK having the largest area, and the passivation layer 116 having a smaller area than that of the first electrode CE1 can be disposed thereon. Each solder pattern SDP can be disposed on each passivation layer 116.

A mirror layer Mir can be disposed between the first electrode CE1 and the passivation layer 116. The fourth conductive layer CE1d is etched and removed in FIG. 14 to expose the second conductive layer CE1b made of the reflective material. Thus, the exposed portion of the second conductive layer CE1b made of the reflective material can act as the mirror layer Mir.

In each of all of the first light-emitting element 130, the second light-emitting element 140, and the third light-emitting element 150 according to the second example embodiment of the present disclosure, the solder pattern SDP can overlap the passivation layer 116, and can also overlap the mirror layer Mir.

Each of the first light-emitting element 130, the second light-emitting element 140, and the third light-emitting element 150 can have an upper end width greater than the width of each solder pattern SDP.

In the second example embodiment of the present disclosure, since the width of each solder pattern SDP is increased, the width of the lower end of each of the first light-emitting element 130, the second light-emitting element 140, and the third light-emitting element 150 can be smaller than the width of each solder pattern SDP.

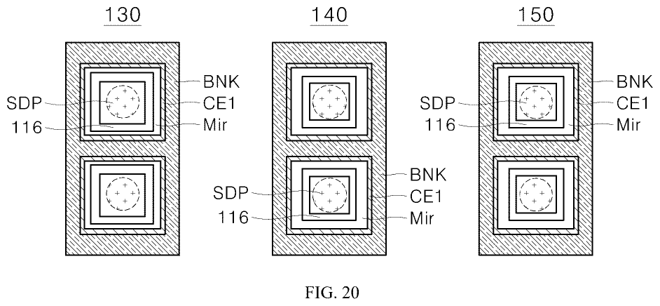

FIG. 20 is a plan view illustrating a display device according to the third example embodiment of the present disclosure.

Referring to FIG. 20, in the display device according to the third example embodiment of the present disclosure, the lower electrode 134 bonded to the first electrode CE1 via the solder pattern SDP can be disposed in the lowest layer of each of the light-emitting elements 130, 140, and 150. In this regard, the lower electrode 134 can be the anode electrode 134.

According to the third example embodiment of the present disclosure, the width of the lower electrode 134 of each of the light-emitting elements 130, 140, and 150 bonded to the first electrode CE1 via the solder pattern SDP can be increased. For example, as the width of the solder pattern SDP bonded to each of the light-emitting elements 130, 140, and 150 increases in the second example embodiment described above, the width of the anode electrode 134 of each of the light-emitting elements 130, 140, and 150 is increased so as to correspond to the increased width of each solder pattern SDP in the third example embodiment of the present disclosure.

In each of the first light-emitting element 130, the second light-emitting element 140, and the third light-emitting element 150 according to the third example embodiment of the present disclosure, the lower electrode 134 thereof can be further increased as the width of the solder pattern SDP contacting the lower electrode 134 has been increased.

In the first light-emitting element 130, a main bonding area can be positioned in one of both opposing sides in the column direction, and a redundant bonding area can be positioned in the other of both opposing sides in the column direction, but not limited thereto.

In the second light-emitting element 140, a redundant bonding area can be located in one of both opposing sides in the column direction, and a main bonding area can be located in the other of both opposing sides in the column direction, but not limited thereto.

In the third light-emitting element 150, a main bonding area can be positioned in one of both opposing sides in the column direction, and a redundant bonding area can be positioned in the other of both opposing sides in the column direction, but not limited thereto.

In each of the main bonding area and the redundant bonding area of each of the light-emitting elements 130, 140, and 150, each solder pattern SDP can be disposed in the uppermost layer thereof.

In the third example embodiment of the present disclosure, since the width of the lower electrode 134 of each of the light-emitting elements 130, 140, and 150 is increased, each solder pattern SDP is disposed inside each bonding area (square) in each of the light-emitting elements 130, 140, and 150.

In each of the light-emitting elements 130, 140, and 150, the first electrode CE1 can be disposed on the bank BNK having the largest area, and the passivation layer 116 having a smaller area than that of the first electrode CE1 can be disposed thereon. Each solder pattern SDP can be disposed on each passivation layer 116.

In each of the light-emitting elements 130, 140, and 150, each solder pattern SDP can be located inwardly of the bonding area (square) so as not to contact an outer boundary of the bonding area (square).

A mirror layer Mir can be disposed between the first electrode CE1 and the passivation layer 116. The fourth conductive layer CE1d is etched and removed in FIG. 14 to expose the second conductive layer CE1b made of the reflective material. Thus, the exposed portion of the second conductive layer CE1b made of the reflective material can act as the mirror layer Mir.

In each of all of the first light-emitting element 130, the second light-emitting element 140, and the third light-emitting element 150 according to the third example embodiment of the present disclosure, the solder pattern SDP can overlap the passivation layer 116 and may not overlap the mirror layer Mir.

Each of the first light-emitting element 130, the second light-emitting element 140, and the third light-emitting element 150 can have an upper end width greater than the width of each solder pattern SDP.

In the third example embodiment of the present disclosure, since the width of the lower electrode 134 of each of the light-emitting elements 130, 140, and 150 is increased, the lower end width of each of the first light-emitting element 130, the second light-emitting element 140, and the third light-emitting element 150 can be greater than or equal to the width of each solder pattern SDP.

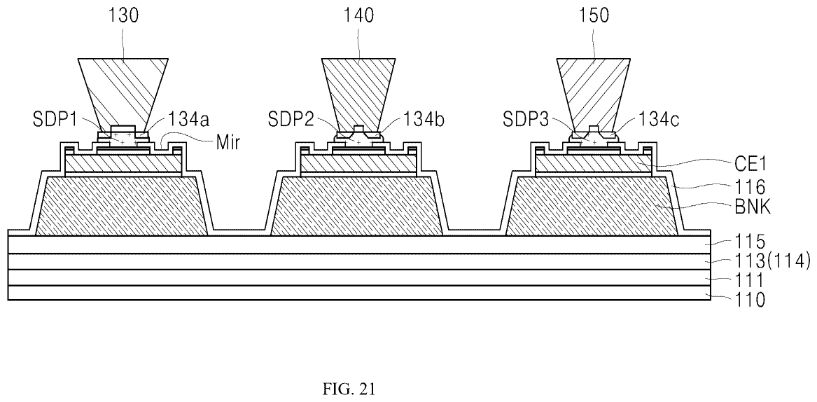

FIG. 21 is a cross-sectional view illustrating light-emitting elements of a display device according to the first example embodiment of the present disclosure.

Referring to FIG. 21, the display device according to the first example embodiment of the present disclosure can include a plurality of light-emitting elements 130, 140, and 150.

The plurality of light-emitting elements 130, 140, and 150 can include, for example, the first light-emitting element 130 emitting red light, the second light-emitting element 140 emitting green light, and the third light-emitting element 150 emitting blue light. Each of the plurality of light-emitting elements 130, 140, and 150 can include one or more sub light-emitting element. For example, each of the plurality of light-emitting elements 130, 140, and 150 can include only one sub light-emitting element. For example, the first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b. However, the disclosure is not limited thereto. For example, the plurality of light-emitting elements ED can include a fourth light-emitting element emitting white light. The fourth light-emitting element can also include one or more sub light-emitting element.

Each of the plurality of light-emitting elements 130, 140, and 150 can have a structure in which each of the first electrodes CE1 is bonded thereto via each of the plurality of solder patterns SDP1, SDP2, and SDP3.

In the first example embodiment of the present disclosure, the thickness of each of the plurality of solder patterns SDP1, SDP2, and SDP3 is increased.

The plurality of solder patterns SDP1, SDP2, and SDP3 can include a first solder pattern SDP1 corresponding to the first light-emitting element 130, a second solder pattern SDP2 corresponding to the second light-emitting element 140, and a third solder pattern SDP3 corresponding to the third light-emitting element 150.

The size of the first light-emitting element 130 can be greater than the size of each of the second light-emitting element 140 and the third light-emitting element 150. For example, when the size of the upper end of the first light-emitting element 130 can be 7 to 7.6 micrometers (μm) and the size of the lower end thereof is 4.7 to 5.3 micrometers (μm), the size of the upper end of each of the second light-emitting element 140 and the third light-emitting element 150 can be 5.7 to 6.3 micrometers (μm) and the size of the lower end thereof can be 3.7 to 4.3 micrometers (μm). For example, when the size of the upper end of the first light-emitting element 130 can be 7.3 micrometers (μm) and the size of the lower end thereof is 5 micrometers (μm), the size of the upper end of each of the second light-emitting element 140 and the third light-emitting element 150 can be 6 micrometers (μm) and the size of the lower end thereof can be 4 micrometers (μm), but not limited thereto.

Since the size of the first light-emitting element 130 is larger than the size of each of the second light-emitting element 140 and the third light-emitting element 150, the first solder pattern SDP1 can have a width greater than the width of each of the second solder pattern SDP2 and the third solder pattern SDP3.

In the display device according to the first example embodiment of the present disclosure, the buffer layer 111 can be disposed on the substrate 110, the protective layers 113 and 114 can be disposed on the buffer layer 111, and the insulating layer 115 can be disposed on the protective layers 113 and 114. For example, the buffer layer 111 and the insulating layer 115 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. For example, each of the protective layers 113 and 114 can be made of a photoresist, polyimide (PI), or a photo acryl-based material. However, example embodiments of the present disclosure are not limited thereto.

In addition, in the display device, a plurality of banks BNK can be disposed on the insulating layer 115, the first electrode CE1 can be disposed on each of the banks BNK, and each of the first solder pattern SDP1, the second solder pattern SDP2, and the third solder pattern SDP3 can be disposed on each of the first electrodes CE1.

The first light-emitting element 130 including a first anode electrode 134a can be disposed on the first solder pattern SDP1.

The second light-emitting element 140 including a second anode electrode 134b can be disposed on the second solder pattern SDP2.

The third light-emitting element 150 including a third anode electrode 134c can be disposed on the third solder pattern SDP3.

The passivation layer 116 can be disposed on some insulating layers 115, the sidewall of the bank BNK, the sidewall of the first electrode CE1, and the upper surface thereof.

In each of the first light-emitting element 130, the second light-emitting element 140, and the third light-emitting element 150, the mirror layer Mir having a partially recessed groove shape can be formed in the passivation layer 116 on each of the first electrodes CE1.

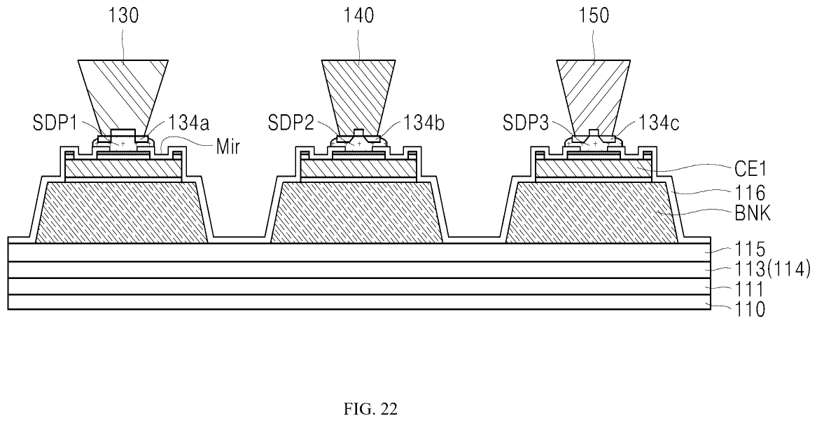

FIG. 22 is a cross-sectional view illustrating light-emitting elements of a display device according to the second example embodiment of the present disclosure.

Referring to FIG. 22, the display device according to the second example embodiment of the present disclosure can include a plurality of light-emitting elements 130, 140, and 150.

The plurality of light-emitting elements 130, 140, and 150 can include, for example, the first light-emitting element 130 emitting red light, the second light-emitting element 140 emitting green light, and the third light-emitting element 150 emitting blue light. Each of the plurality of light-emitting elements 130, 140, and 150 can include one or more sub light-emitting element. For example, each of the plurality of light-emitting elements 130, 140, and 150 can include only one sub light-emitting element. For example, the first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b. However, the disclosure is not limited thereto. For example, the plurality of light-emitting elements ED can include a fourth light-emitting element emitting white light. The fourth light-emitting element can also include one or more sub light-emitting element.

Each of the plurality of light-emitting elements 130, 140, and 150 can have a structure in which each of the first electrodes CE1 is bonded thereto via each of the plurality of solder patterns SDP1, SDP2, and SDP3.

In the second example embodiment of the present disclosure, width (CD) of each of the plurality of solder patterns SDP1, SDP2, and SDP3 is increased.

The first solder pattern SDP1 can have a width smaller than an upper end width of the first light-emitting element 130 and larger than a lower end width of the first light-emitting element 130.

The second solder pattern SDP 2 can have a width smaller than an upper end width of the second light-emitting element 140 and larger than a lower end width of the second light-emitting element 140.

The third solder pattern SDP3 can have a width smaller than the upper end width of the third light-emitting element 150 and larger than the lower end width of the third light-emitting element 150.

In the display device according to the second example embodiment of the present disclosure, the buffer layer 111 can be disposed on the substrate 110, the protective layers 113 and 114 can be disposed on the buffer layer 111, and the insulating layer 115 can be disposed on the protective layers 113 and 114. For example, the buffer layer 111 and the insulating layer 115 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. For example, each of the protective layers 113 and 114 can be made of a photoresist, polyimide (PI), or a photo acryl-based material. However, example embodiments of the present disclosure are not limited thereto.

In addition, in the display device, a plurality of banks BNK can be disposed on the insulating layer 115, each first electrode CE1 can be disposed on each of the banks BNK, and each of the first solder pattern SDP1, the second solder pattern SDP2, and the third solder pattern SDP3 can be disposed on each of the first electrodes CE1.

The first light-emitting element 130 including the first anode electrode 134a can be disposed on the first solder pattern SDP1.

The second light-emitting element 140 including the second anode electrode 134b can be disposed on the second solder pattern SDP2.

The third light-emitting element 150 including the third anode electrode 134c can be disposed on the third solder pattern SDP3.

The passivation layer 116 can be disposed on some insulating layers 115, the sidewall of the bank BNK, the sidewall of the first electrode CE1, and the upper surface thereof.

The mirror layer Mir can be disposed between the first electrode CE1 and the passivation layer 116. The fourth conductive layer CE1d is etched and removed in FIG. 14 to expose the second conductive layer CE1b made of the reflective material. Thus, the exposed portion of the second conductive layer CE1b made of the reflective material can act as the mirror layer Mir.

In each of the first light-emitting element 130, the second light-emitting element 140, and the third light-emitting element 150, the mirror layer Mir having a partially recessed groove shape can be formed in the passivation layer 116 on each of the first electrodes CE1.

At least one of the first solder pattern SDP1, the second solder pattern SDP2, and the third solder pattern SDP3 can partially overlap the mirror layer Mir.

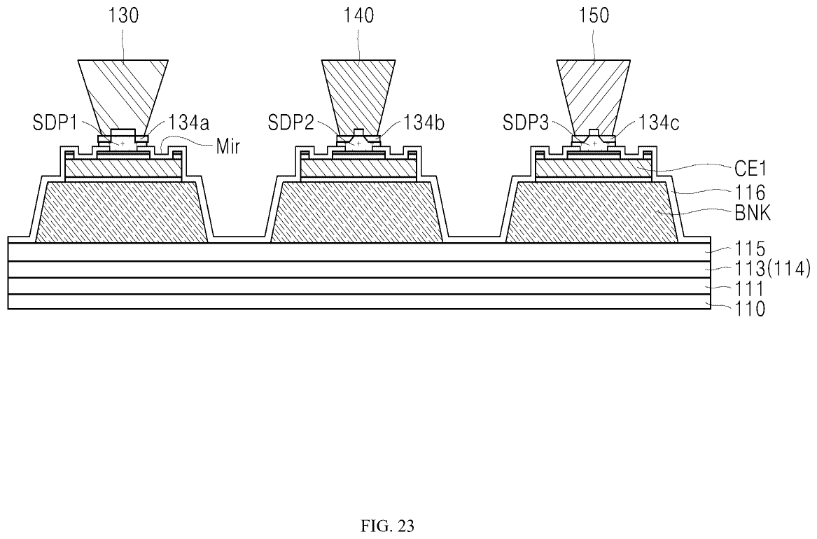

FIG. 23 is a cross-sectional view illustrating light-emitting elements of a display device according to the third example embodiment of the present disclosure.

Referring to FIG. 23, the display device according to the third example embodiment of the present disclosure can include a plurality of light-emitting elements 130, 140, and 150.

The plurality of light-emitting elements 130, 140, and 150 can include, for example, the first light-emitting element 130 emitting red light, the second light-emitting element 140 emitting green light, and the third light-emitting element 150 emitting blue light. Each of the plurality of light-emitting elements 130, 140, and 150 can include one or more sub light-emitting element. For example, each of the plurality of light-emitting elements 130, 140, and 150 can include only one sub light-emitting element. For example, the first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b. However, the disclosure is not limited thereto. For example, the plurality of light-emitting elements ED can include a fourth light-emitting element emitting white light. The fourth light-emitting element can also include one or more sub light-emitting element.

Each of the plurality of light-emitting elements 130, 140, and 150 can have a structure in which each of the first electrodes CE1 is bonded thereto via each of the plurality of solder patterns SDP1, SDP2, and SDP3.

In the third example embodiment of the present disclosure, the width of each of the respective lower electrodes 134a, 134b, and 134c of the light-emitting elements 130, 140, and 150 corresponding to the plurality of solder patterns SDP1, SDP2, and SDP3 is increased.

The plurality of solder patterns SDP1, SDP2, and SDP3 can include a first solder pattern SDP1 corresponding to the first light-emitting element 130, a second solder pattern SDP2 corresponding to the second light-emitting element 140, and a third solder pattern SDP3 corresponding to the third light-emitting element 150.

In the display device according to the third example embodiment of the present disclosure, the buffer layer 111 can be disposed on the substrate 110, the protective layers 113 and 114 can be disposed on the buffer layer 111, and the insulating layer 115 can be disposed on the protective layers 113 and 114. For example, the buffer layer 111 and the insulating layer 115 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. For example, each of the protective layers 113 and 114 can be made of a photoresist, polyimide (PI), or a photo acryl-based material. However, example embodiments of the present disclosure are not limited thereto.

In addition, in the display device, a plurality of banks BNK can be disposed on the insulating layer 115, each first electrode CE1 can be disposed on each of the banks BNK, and each of the first solder pattern SDP1, the second solder pattern SDP2, and the third solder pattern SDP3 can be disposed on each of the first electrodes CE1.

The first light-emitting element 130 including the first anode electrode 134a can be disposed on the first solder pattern SDP1.

The second light-emitting element 140 including the second anode electrode 134b can be disposed on the second solder pattern SDP2.

The third light-emitting element 150 including the third anode electrode 134c can be disposed on the third solder pattern SDP3.

The passivation layer 116 can be disposed on some insulating layers 115, the sidewall of the bank BNK, the sidewall of the first electrode CE1, and the upper surface thereof.

The size of the first light-emitting element 130 can be greater than the size of each of the second light-emitting element 140 and the third light-emitting element 150.

The lower electrode 134a of the first light-emitting element 130 can have a width greater than the width of each of the respective lower electrodes 134b and 134c of the second light-emitting element 140 and the third light-emitting element 150.

The first solder pattern SDP1 can have a width smaller than an upper end width of the first light-emitting element 130 and smaller than or equal to a lower end width of the first light-emitting element 130.

The second solder pattern SDP2 can have a width smaller than an upper end width of the second light-emitting element 140 and smaller than or equal to a lower end width of the second light-emitting element 140.

The third solder pattern SDP3 can have a width smaller than an upper end width of the third light-emitting element 150 and smaller than or equal to a lower end width of the third light-emitting element 150.

The mirror layer Mir can be disposed between the first electrode CE1 and the passivation layer 116. The fourth conductive layer CE1d is etched and removed in FIG. 14 to expose the second conductive layer CE1b made of the reflective material. Thus, the exposed portion of the second conductive layer CE1b made of the reflective material can act as the mirror layer Mir.

In each of the first light-emitting element 130, the second light-emitting element 140, and the third light-emitting element 150, the mirror layer Mir having a partially recessed groove shape can be formed in the passivation layer 116 on each of the first electrodes CE1.

All of the first solder pattern SDP1, the second solder pattern SDP2, and the third solder pattern SDP3 may not overlap the mirror layer Mir.

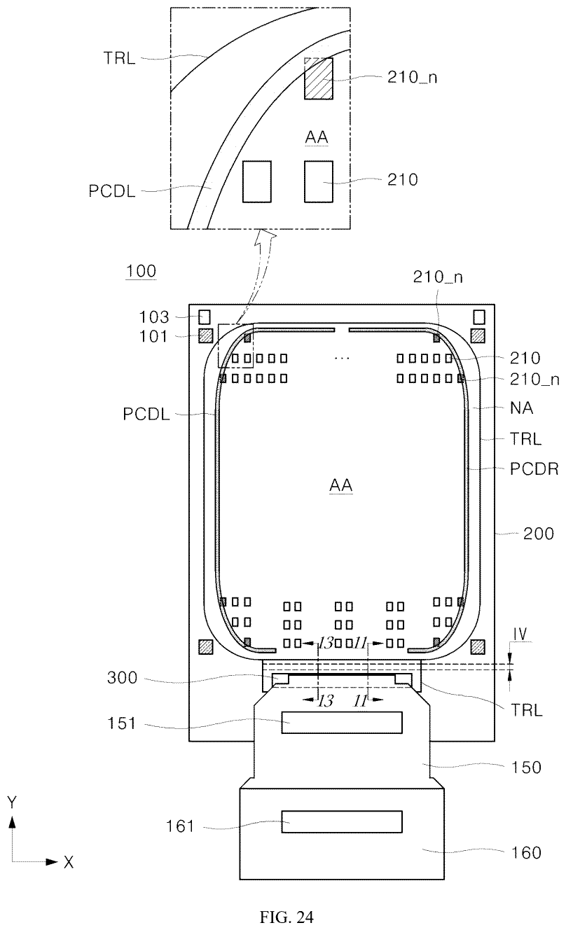

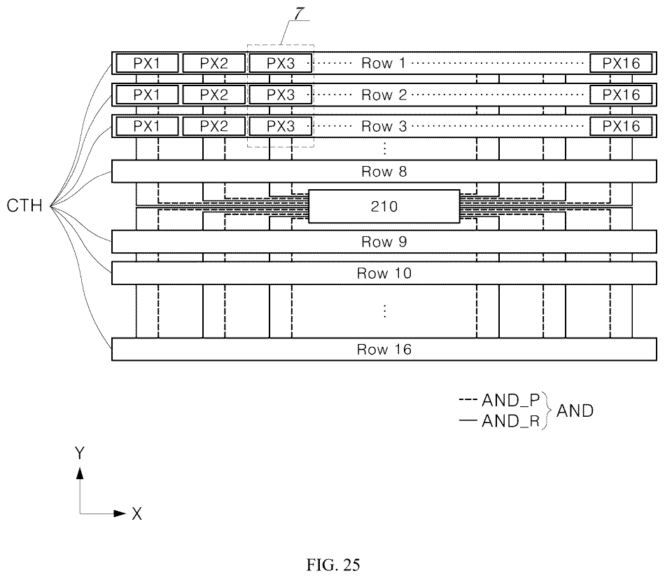

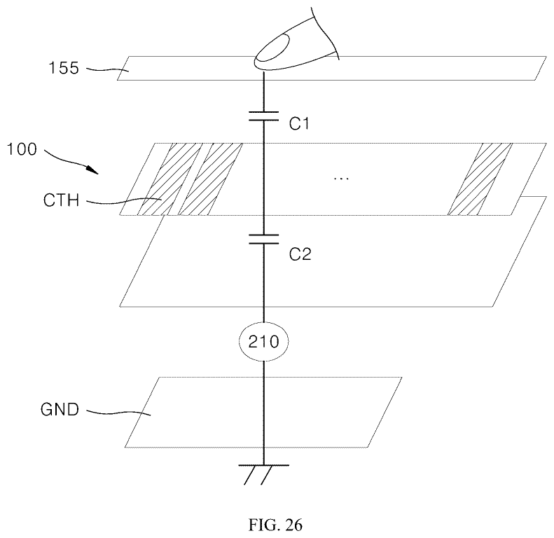

FIG. 24 is a plan view of a display device according to another example embodiment of the present disclosure. FIG. 25 is a plan view illustrating an area in which one pixel driving circuit among a plurality of pixel driving circuits of FIG. 24 is disposed. FIG. 26 is a view illustrating a touch operation of a display device according to another example embodiment of the present disclosure.

Referring to FIGS. 24 and 25, in a display area AA of a substrate 200 according to another example embodiment of the present disclosure, a plurality of pixels PX1, PX2, PX3, . . . , PX16 including a plurality of driving chips 210 as the pixel driving circuits PD and a plurality of light-emitting elements electrically connected to the driving chips 210 can be arranged. Each driving chip 210 can supply a control signal and power to the plurality of light-emitting elements to control a light-emitting operation of the plurality of light-emitting elements.

The substrate 200 can have a shape in which a length of one side is larger than a length of the other side. For example, the substrate 200 can include a long side having a larger length and a short side having a smaller length than that of the long side. The short side can extend in the first direction X of the substrate 200, and the long side can extend in the second direction Y of the substrate 200. Alternatively, the long side can extend in the first direction X of the substrate 200, and the short side can extend in the second direction Y of the substrate 200. However, example embodiments of the present disclosure are not limited thereto.

One or more crack detection lines PCDL and PCDR can be disposed in a partial area of the non-display area NA. Each of the one or more crack detection lines PCDL and PCDR can extend along an outer edge of the display area AA and can detect a defect such as a crack that can occur in the outer edge of the display area AA. The one or more crack detection lines PCDL and PCDR can extend along at least both opposing sides and a portion of each of upper and lower sides of the display area AA. For example, the one or more crack detection lines PCDL and PCDR can include a first crack detection line PCDL and a second crack detection line PCDR.

The first crack detection line PCDL can extend along a left long side of the substrate 200 and can extend to each of upper and lower left corners and then can extend along a left portion of each of upper and lower short sides. The second crack detection line PCDR can extend along a right long side of the substrate 200 and can extend to each of upper and lower right corners and then can extend along a right portion of each of the upper and lower short sides. The first crack detection line PCDL and the second crack detection line PCDR. can be spaced apart from each other.

Each of the first crack detection line PCDL and the second crack detection line PCDR can be disposed to overlap some of the plurality of driving chips 210 at each corner area. The driving chip DC disposed to overlap the first and second crack detection lines PCDL and PCDR in the corner area can be an inactive driving chip 210_n.

The inactive driving chip 210_n can be disposed to overlap the first crack detection line PCDL or the second crack detection line PCDR at the corner area of the substrate 200, and thus may not be electrically connected to at least a portion of the power line or the signal line. Accordingly, the inactive driving chip 210_n can be an unused driving chip that does not control the plurality of light-emitting elements. The inactive driving chip 210_n can include at least eight driving chips arranged along the four corner areas of the substrate 200 among the plurality of driving chips 210. For example, two inactive driving chips 210_n can be disposed in each of the four corner areas of the substrate 200.

The substrate 200 can include a trimming line TRL extending along an outer edge of the non-display area NA. The trimming line TRL can be a cutting line cut by a laser beam during a scribing process for dividing the substrate 200 into a plurality of display panels 100 (see FIG. 1) as individual units. An area disposed outwardly of the trimming line TRL can be removed in the scribing process.

A plurality of alignment key patterns 101 and 103 can be disposed in the area disposed outwardly of the trimming line TRL. The plurality of alignment key patterns 101 and 103 can include a first alignment key pattern 101 and a second alignment key pattern 103. However, example embodiments of the present disclosure are not limited thereto. Since the plurality of alignment key patterns 101 and 103 are disposed in the area disposed outwardly of the trimming line TRL, they can be removed in the scribing process.

The first alignment key pattern 101 can be a pattern for alignment between the display panel 100 and the cover member 155 of FIG. 1. At least one of the plurality of first alignment key patterns 101 can be positioned in the area disposed outwardly of the trimming line TRL facing each corner area of the substrate 200. For example, each first alignment key patterns 101 can be disposed at each of four corner areas of the substrate 200. Thus, the plurality of first alignment key patterns 101 can include four alignment key patterns.

The second alignment key pattern 103 can include various alignment key patterns for aligning components respectively disposed in different layers, such as a plurality of signal lines, contact holes, and a plurality of driving chips disposed on the substrate 200 at correct positions. The second alignment key pattern 103 can include a metal material. Accordingly, the second alignment key pattern 103 can be disposed on the display area AA or the non-display area NA and can be formed at the same time as a time at which a plurality of signal lines including a metal material is formed. However, example embodiments of the present disclosure are not limited thereto.

The plurality of driving chips 210 as the pixel driving circuits can be disposed on the display area AA of the substrate 200. For example, the plurality of driving chips 210 can be arranged in a matrix shape. However, example embodiments of the present disclosure are not limited thereto.

A plurality of pixels including a plurality of light-emitting elements can be arranged in a matrix shape while being respectively disposed on the plurality of driving chips 210. The plurality of pixels can be arranged to be spaced apart from each other in each of the first direction DR1 and the second direction DR2 intersecting the first direction DR1. The first direction can be an X-axis direction of the display panel 100, and the second direction can be a Y-axis direction of the substrate 200. However, example embodiments are not limited thereto. For example, the first direction can be a transverse direction or a row direction of the substrate 200, and the second direction can be a longitudinal direction or a column direction of the substrate 200.

In each of the plurality of pixels, sub-pixels respectively emitting different colors can be alternately arranged with each other in the first direction DR1 of the substrate 200. In addition, sub-pixels emitting the same color can be arranged in the second direction DR2 of the substrate 200. For example, the first to 16th pixels PX1 to PX16 can be arranged in the row direction as the first direction. One pixel PX can include red (R), green (G), and blue (B) sub-pixels.

A plurality of light-emitting element can be disposed in each of the sub-pixels. At least one light-emitting element can be disposed in one sub-pixel. For example, two light-emitting elements can be disposed in one sub-pixel. One of the two light-emitting elements can act as a main light-emitting element, and the other thereof can act as a redundant light-emitting element. The light-emitting element can be embodied as a micro LED (μLED). Accordingly, the red (R), green (G), and blue (B) sub-pixels can be repeatedly arranged in this order in the first direction, for example, the row direction.

In addition, the sub-pixels emitting light of the same color can be arranged in the column direction as the second direction. For example, the sub-pixels emitting light of one color among red (R), green (G), and blue (B) colors can be arranged in the column direction as the second direction. The sub-pixels emitting light of the same color can be electrically connected to each other via one first electrode AND_P and AND_R.

The first electrode AND can include a first line AND_P and a second line AND_R. The first line AND_P and the second line AND_R can be spaced apart from each other in the first direction DR1 of the substrate 200. The first line AND_P of the first electrode AND can be connected to the main light-emitting element, and the second line AND_P of the first electrode AND can be connected to the redundant light-emitting element, but not limited thereto.

Each of a plurality of second electrodes CTH can extend in the first direction. In addition, the plurality of second electrodes CTH can be arranged to be spaced apart from each other in the second direction. Accordingly, each of the second electrodes CTH can extend in the first direction and can be connected to the first pixel PX1 to the 16th pixel PX16 arranged in each of a plurality of rows Row 1, Row2, Row 3, . . . , Row 16.

Each of the plurality of driving chips 210 can include a plurality of driving circuits to drive the plurality of light-emitting elements. One driving chip 210 can be connected to the plurality of first electrodes AND and the plurality of second electrodes CTH respectively connected to the plurality of pixels PX1, PX2, PX3, . . . , PX16. For example, one driving chip 210 can drive the plurality of light-emitting elements arranged in the first row Row1 to the 16th row Row 16. In other words, one driving chip 210 can be electrically connected to the plurality of light-emitting elements arranged in the first row Row 1 to the 16th row Row 16 via the first electrodes AND and the second electrodes CTH, and can supply a control signal and power thereto via the first electrodes AND and the second electrodes CTH to control the light-emitting operations of the plurality of light-emitting elements.

The plurality of first electrodes AND connected to at least one driving chip 210 can be radially connected thereto to connect each of the first sub-pixel SP1 disposed at a first position of the first row Row1 to the 16th sub-pixel SP16 opposite to the first sub-pixel SP1 and disposed at a 16th position thereof to the driving chip 210. For example, a shape in which the plurality of first electrodes AND are connected to the driving chip 210 can be a rhombus shape or a ‘I’ shape in a plan view of the device.

The display device according to an example embodiment of the present disclosure can have an in-cell touch structure in which each of the plurality of second electrodes CTH is used as a touch electrode instead of forming a separate touch electrode. Accordingly, since the separate touch electrode is not formed, a thickness of the display panel can be reduced.

Referring to FIG. 26, when a user's touch operation is performed on the cover member 155, a change in a first capacitance C1 between each of the plurality of second electrodes CTH disposed on the substrate of the display panel 100 and the cover member 155 and a change in a second capacitance C2 between each of the plurality of second electrodes CTH and each of a plurality of signal lines M_SL can be detected and provided to the driving chip 210. In addition, the driving chip 210 can perform a touch control function to provide a control signal based on the touch input to the plurality of light-emitting elements. A ground GND can be disposed to be opposite to the cover member 155 while the plurality of second electrodes CTH are disposed between the cover member and the ground.

A touch sensing scheme of a capacitance substrate can include a self-capacitance operation scheme and a mutual capacitance operation scheme for sensing a touch based on a detecting result of a change in a capacitance between two types of touch sensors.

The display device 1000 according to an example embodiment of the present disclosure can perform the touch operation and the touch sensing in the self-capacitance-based touch sensing scheme, or can perform the touch operation and the touch sensing in the mutual-capacitance-based touch sensing scheme.

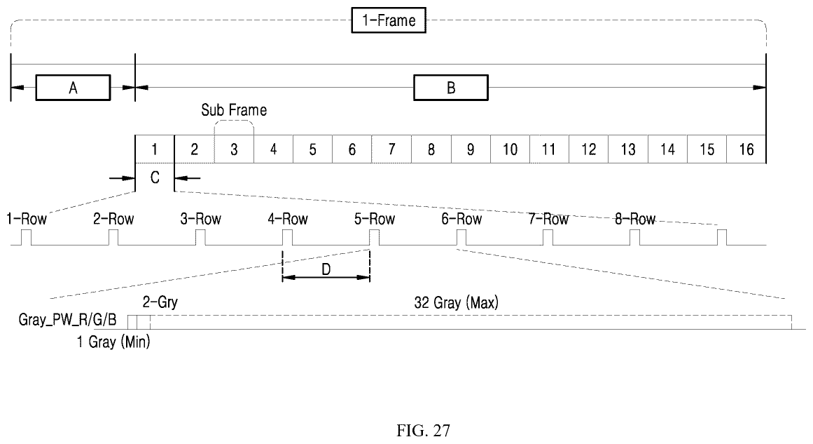

FIG. 27 illustrates an example of a signal waveform diagram when a display device according to an example embodiment of the present disclosure operates.

Referring to FIG. 27, the display device according to an example embodiment of the present disclosure can perform a light emission operation on one frame basis.

One frame can include a touch period A and a display period B.

One frame can operate at a frequency of, for example, 60 Hz. In this case, the touch period A can operate for a first time duration at a frequency of, for example, 60 Hz, and the display period B can operate for a second time duration larger than the first time duration at a frequency of, for example, 60 Hz. Accordingly, the operation time duration of the touch period A and the operation time duration of the display period B in one frame can be different from each other. For example, the operation time duration of the touch period A can be shorter than the operation time duration of the display period B.

The display period B can include 16 sub-frames.

For example, when, in the display panel DP, eight light-emitting elements are connected to one anode electrode line as the first electrode, one sub-frame period C can include eight pulse signals 1-Row, 2-Row, 3-Row, 4-Row, 5-Row, 6-Row, 7-Row, and 8-Row. For example, in an example embodiment of the present disclosure, eight micro light-emitting elements (μLED) can operate during one sub frame.

Accordingly, in an example embodiment of the present disclosure, one frame includes 16 sub-frames and one sub-frame includes 8 pulse signals, such that 128 micro light-emitting elements (μLED) can operate for one frame.

An example embodiment of the present disclosure is not limited thereto. For example, when 16 micro light-emitting elements (μLED) are connected to one anode electrode line as the first electrode, one sub-frame period C can include 16 pulse signals. In this case, 256 micro light-emitting elements (μLED) can operate for one frame.

One pulse signal (e.g., 5-Row) drives one micro light-emitting element (μLED). One pulse signal period D can include a high signal period and a low signal period. In this regard, a time duration of the low signal period can be larger than a time duration of the high signal period.

In an example embodiment of the present disclosure, an operation time duration of the micro light-emitting element (μLED) can be controlled based on a light-emission signal EM applied to the gate electrode of the light-emission transistor TEM.

A micro driver (μDriver) can control an application time duration of the light-emission signal EM based on a pulse width PW. For example, a case in which one pulse signal (e.g., 5-Row) is applied to the gate electrode of the light-emission transistor TEM using one pulse width PW can be referred to as one gray.

In order to control the application time duration of the light-emission signal EM, the micro driver (μDriver) can apply one pulse signal (e.g., 5-Row) using the pulse width PW varying from a minimum of 1 Gray (Min) to a maximum of 32 Gray (Max).

One pixel PX can include red (R), green (G), and blue (B) sub-pixels. Each of the plurality of micro light-emitting elements (μLED) can be disposed in the sub-pixel.

Accordingly, the micro driver (μDriver) can control a light-emission time duration of the micro light-emitting element (μLED) corresponding to each of red (R), green (G), and blue (B) sub-pixels by applying the pulse signal of which the pulse width PW is adjusted from a minimum of 1 Gray (Min) to a maximum of 32 Gray (Max) to the gate electrode of the light-emission transistor TEM.

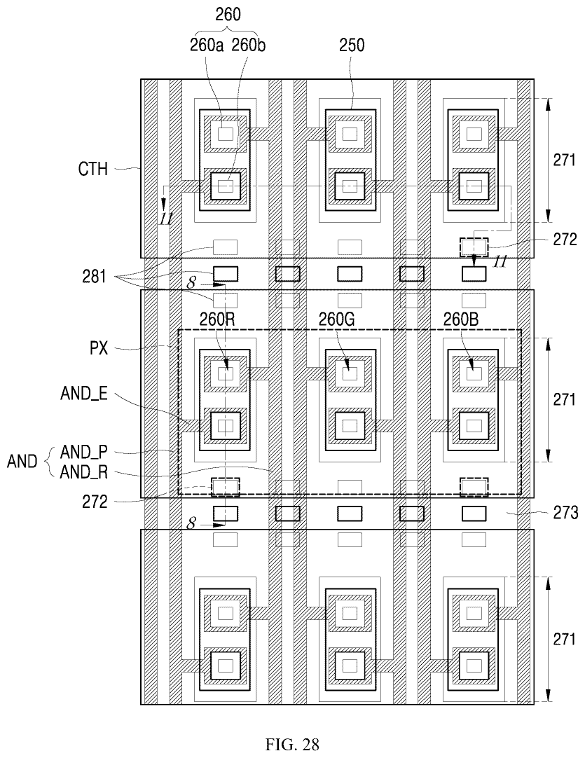

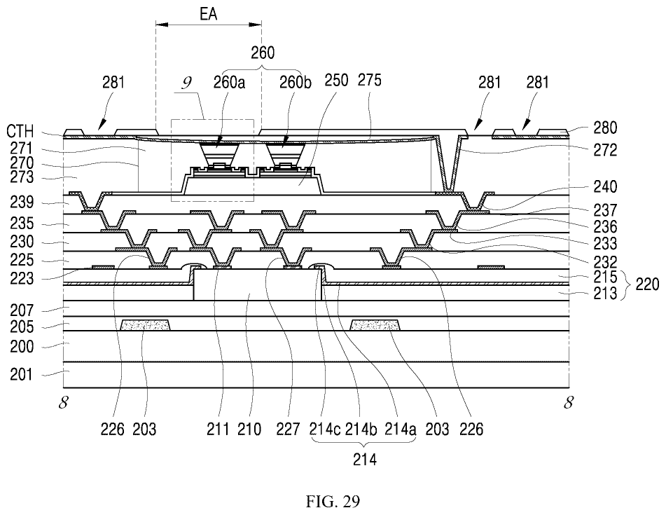

FIG. 28 is an enlarged plan view illustrating an area 7 of FIG. 25 according to another example embodiment of the present disclosure. FIG. 29 is a cross-sectional view taken along a line 8-8 of FIG. 28. For convenience of illustration, FIG. 28 illustrates the first electrode AND, the second electrode CTH, a plurality of light-emitting elements 260, a bank 250, optical insulating layers 271 and 273.

Referring to FIGS. 28 and 29, the display device according to another example embodiment of the present disclosure can include a plurality of first electrodes AND arranged and disposed on the substrate 200, the solder pattern SDP disposed on a plurality of first electrodes AND, the plurality of light-emitting elements 260 electrically connected to the plurality of first electrodes AND, the optical insulating layers 271 and 273, a plurality of second electrodes CTH disposed on the plurality of light-emitting elements 260, and a contact electrode 272.

The plurality of first electrodes AND can be arranged to be spaced apart from each other in the first direction of the substrate 200. The plurality of first electrodes AND can extend in the second direction intersecting the first direction. The first direction can be an X-axis direction of the substrate 200, and the second direction can be a Y-axis direction of the substrate 200. However, example embodiments are not limited thereto. For example, the first direction can be a transverse direction or a row direction of the substrate 200, and the second direction can be a longitudinal direction or a column direction of the substrate 200.

The plurality of first electrodes AND can include a first line AND_P and a second line AND_R. The first line AND_P and the second line AND_R can be spaced apart from each other in the first direction DR1 of the substrate 200. Each of the first line AND_P and the second line AND_R can include an extension portion AND_E electrically connected to the light-emitting element 260.

Each of the first line AND_P and the second line AND_R of the plurality of first electrodes AND can be connected to the solder pattern SDP. The plurality of light-emitting elements 260 can be respectively disposed on the plurality of bonding pads 257.

The plurality of second electrodes CTH can be disposed on the plurality of light-emitting elements 260. The plurality of second electrodes CTH can be arranged to be spaced apart from each other in the second direction of the substrate 200.

The plurality of second electrodes CTH can extend in the first direction intersecting the second direction. The first direction can be an X-axis direction of the substrate 200, and the second direction can be a Y-axis direction of the substrate 200. However, example embodiments are not limited thereto. For example, the first direction can be a transverse direction or a row direction of the substrate 200, and the second direction can be a longitudinal direction or a column direction of the substrate 200.

Each of the plurality of first electrodes AND can be referred to as a pixel electrode. Each of the plurality of second electrodes CTH can be referred to as a common electrode. However, example embodiments of the present disclosure are not limited thereto. For example, each of the plurality of first electrodes AND can correspond to the first electrode CE1 of FIG. 8. In addition, each of the plurality of second electrodes CTH can correspond to the second electrode CE2 of FIG. 8.

The plurality of pixels PX can be disposed on the substrate 200. The plurality of pixels PX can be arranged so as to be spaced from each other via a spacing area. One pixel can include a plurality of sub-pixels that emit light of different colors, respectively. For example, the plurality of sub-pixels can include a first sub-pixel 260R that emits red light, a second sub-pixel 260G that emits green light, and a third sub-pixel 260B that emits blue light. However, the present disclosure is not limited thereto, the plurality of sub-pixels can also include a fourth sub-pixel that emits white light.

A plurality of opening areas 281 can be disposed in the spacing area defined between neighboring pixels PX. The plurality of opening areas 281 can be defined by a light blocking pattern 280 as shown in FIG. 29. The plurality of opening areas 281 can be disposed at a position corresponding to an ALS (Ambient Light System).

Referring to FIG. 29, the substrate 200 can be an insulating substrate including a plastic or polymer material having flexibility. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the substrate 200 can include a single layer or a multilayer structure including polyimide, polycarbonate, or polyethylene terephthalate. However, example embodiments of the present disclosure are not limited thereto. The substrate 200 can be a silicon substrate or a glass substrate.

A carrier substrate 201 can be disposed on a rear surface of the substrate 200. The carrier substrate 201 can be made of a material that is relatively harder than the substrate 200 having flexibility. The carrier substrate 201 can be omitted. In addition, the carrier substrate 201 can be subsequently removed.

A plurality of chip alignment patterns 203 can be disposed on a front surface of the substrate 200 facing the rear surface. The plurality of chip alignment patterns 203 can define a position where the driving chip 210 is to be positioned. The plurality of chip alignment patterns 203 can include a metal material.

A buffer layer 205 can be disposed on the substrate 200 and the plurality of chip alignment patterns 203. The buffer layer 205 can cover the plurality of chip alignment patterns 203 to planarize steps resulting from the plurality of chip alignment patterns 203. The buffer layer 205 can be formed as a single layer or multiple layers made of an organic insulating material or an inorganic insulating material. For example, the organic insulating material can include acrylic resin or photosensitive polyimide. However, example embodiments of the present disclosure are not limited thereto. The inorganic insulating material can include silicon oxide (SiOx) or silicon nitride (SiNx). However, example embodiments of the present disclosure are not limited thereto. The buffer layer 205 can include a multilayer structure in which organic insulating material layers and inorganic insulating material layers are alternately stacked on top of each other.

An adhesive layer 207 can be disposed on the buffer layer 205. The adhesive layer 207 can include an acrylic adhesive material.

A plurality of driving chips 210 can be disposed on the adhesive layer 207. The plurality of driving chips 210 can include a plurality of driving circuits to drive the plurality of light-emitting elements. Accordingly, the plurality of light-emitting elements can be driven based on the same control signal provided from the driving chip 210.

Each of the plurality of driving chips 210 can include pad electrodes 211 disposed on an upper surface thereof.

A planarization layer 220 covering the plurality of driving chips 210 can be disposed on the adhesive layer 207. The planarization layer 220 can include a first planarization layer 213 and a second planarization layer 215. A protective film 214 can be disposed between the first planarization layer 213 and the second planarization layer 215.

The first planarization layer 213 can have a thickness corresponding to a portion of a vertical dimension of a side surface of each of the plurality of driving chips 210. The first planarization layer 213 can include an organic insulating material. For example, the first planarization layer 213 can include a PAC (Photo Active Compound). However, example embodiments of the present disclosure are not limited thereto.

The protective film 214 can include a first portion 214a disposed on an upper surface of the first planarization layer 213, a third portion 214c disposed on an upper edge portion of each of the plurality of driving chips 210, and a second portion 214b disposed between the first portion 214a and the third portion 214c. The second portion 214b can connect the first portion 214a and the third portion 214c to each other, and can cover a portion of the side surface of each of the plurality of driving chips 210.

The protective film 214 can enhance an adhesive force between each of the plurality of driving chips 210 and the planarization layer 220 to prevent a void from being formed between each of the plurality of driving chips 210 and the planarization layer 220. Preventing the occurrence of the void can resulting in preventing moisture or a chemical solution from penetrating into the plurality of driving chips 210 during a manufacturing process. The protective film 214 can include an inorganic insulating material. For example, the protective film 214 can include silicon nitride (SiN).

The second planarization layer 215 can be disposed on the protective film 214. The second planarization layer 215 can cover the third portion 214c of the protective film 214 and can include an opening hole defined therein exposing the pad electrode 211 of each of the plurality of driving chips 210. The second planarization layer 215 can include an organic insulating material. For example, the second planarization layer 215 can include a photoactive composite (PAC). However, example embodiments of the present disclosure are not limited thereto.

A plurality of wiring patterns 223 can be disposed on the second planarization layer 215. The plurality of wiring patterns 223 and the pad electrodes 211 of the plurality of driving chips 210 can be disposed at the same vertical level. The plurality of wiring patterns 223 can be referred to as a plurality of (1-1)-th connection lines.

At least one insulating layer 225, 230, 235, and 239 covering the plurality of driving chips 210 can be disposed on the second planarization layer 215. The one or more insulating layers 225, 230, 235, and 239 can include a first insulating layer 225, a second insulating layer 230, a third insulating layer 235, and a fourth insulating layer 239. However, example embodiments of the present disclosure are not limited thereto.

The first insulating layer 225 can be disposed on the second planarization layer 215 and can have each first contact hole 226 defined therein exposing each of the pad electrode 211 of each of the plurality of driving chips 210 and each of the plurality of wiring patterns 223. The second insulating layer 225 can be disposed on the first insulating layer 225 and can have a second contact hole 232 defined therein. The third insulating layer 235 can be disposed on the second insulating layer 225 and can have a third contact hole 236 defined therein. The fourth insulating layer 239 can be disposed on the third insulating layer 235, and can have a fourth contact hole 240 defined therein. The first contact hole 226, the second contact hole 232, the third contact hole 236, and the fourth contact hole 240 can be positioned so as not to overlap each other in the vertical direction. However, example embodiments of the present disclosure are not limited thereto.

Each of the at least one or more insulating layers 225, 230, 235, and 239 can include a plurality of signal lines 227, 233, 237, and 241 electrically connecting the plurality of driving chips 210 and the plurality of light-emitting elements 260 to each other.

The plurality of signal lines 227, 233, 237, and 241 can include a first signal line 227, a second signal line 233, a third signal line 237, and a fourth signal line 241.

The first signal line 227 can be disposed on the first contact hole 227 of the first insulating layer 225 and can be electrically connected to the pad electrode 211 and the plurality of wiring patterns 223. The second signal line 233 can be disposed on the second contact hole 232 of the second insulating layer 225 and can be electrically connected to the first signal line 227. The third signal line 237 can be disposed on the third contact hole 236 of the third insulating layer 235 and can be electrically connected to the second signal line 233. The fourth signal line 241 can be disposed on the fourth contact hole 240 of the fourth insulating layer 239 and can be electrically connected to the third signal line 237.

The first signal line 227, the second signal line 233, the third signal line 237, and the fourth signal line 241 can be connected to each other in the vertical direction to electrically connect the plurality of driving chips 210 and the plurality of light-emitting elements 260 to each other. The fourth signal line 241 can be electrically connected to the second electrode CTH. Accordingly, the control signal provided from the plurality of driving chips 210 can be transmitted to the plurality of light-emitting elements 260 to drive the plurality of light-emitting elements 260.

While the plurality of signal lines 227, 233, 237, and 241 are formed, at least one of the plurality of alignment key patterns 101 and 103 as shown in FIG. 17 can be formed. For example, while the third signal line 237 and the fourth signal line 241 are formed, the plurality of second alignment key patterns 103 can be formed.

A plurality of banks 250 can be disposed on the fourth insulating layer 239. Each of the plurality of banks 250 can distinguish adjacent sub-pixels from each other. Each of the plurality of banks 250 can include an organic insulating material. For example, the organic insulating material can include polyimide (PI). However, example embodiments of the present disclosure are not limited thereto.

The plurality of first electrodes AND can be disposed on the plurality of banks 250. Each solder pattern SDP can be disposed on each of the plurality of first electrodes AND. Each of the plurality of light-emitting elements 260 can be mounted on each solder pattern SDP and thus can be electrically connected to each of the plurality of first electrodes AND via each bonding pad.

At least one light-emitting element 260 can be disposed on each of the plurality of banks 250. For example, two light-emitting elements 260a and 260b emitting light of the same color can be disposed on one bank 250. One of the two light-emitting elements 260a and 260b can act as the main light-emitting element 260a, and the other thereof can act as the redundant light-emitting element 260b. However, the present disclosure is not limited thereto.

As described above, according to an example embodiment of the present disclosure, a display device capable of reducing the non-transfer of the light-emitting element can be provided.

In addition, according to an example embodiment of the present disclosure, a display device capable of accurately transferring a light-emitting element to a target position on a panel substrate in a transfer process can be provided.

In addition, according to an example embodiment of the present disclosure, a display device capable of improving a transfer process speed can be provided.

The display device according to various aspects and example embodiments of the present disclosure can be described as follows.

A first aspect of the present disclosure provides a display device comprising: a substrate; a driving chip disposed on the substrate; a plurality of light-emitting elements disposed on top of the driving chip and electrically connected to the driving chip; a plurality of first electrodes respectively disposed under the plurality of light-emitting elements; and a plurality of solder patterns respectively disposed on upper surfaces of the plurality of first electrodes so as to respectively overlap the plurality of light-emitting elements, wherein each of the light-emitting elements is bonded to each of the first electrodes via each of the solder patterns.

In accordance with some example embodiments of the first aspect of the present disclosure, the solder pattern has a greater thickness than a thickness of a lower electrode of the light-emitting element.

In accordance with some example embodiments of the first aspect of the present disclosure, the solder pattern has a thickness smaller than a thickness of the first electrode.

In accordance with some example embodiments of the first aspect of the present disclosure, the display device further comprises a passivation layer disposed on the first electrode, wherein the solder pattern has a greater thickness than a thickness of the passivation layer.

In accordance with some example embodiments of the first aspect of the present disclosure, the solder pattern is made of indium, tin, or an alloy thereof.

In accordance with some example embodiments of the first aspect of the present disclosure, in each of all of the plurality of light-emitting elements, the solder pattern overlaps the passivation layer vertically.

In accordance with some example embodiments of the first aspect of the present disclosure, the solder pattern has a width smaller than a width of an upper end of the light-emitting element.

In accordance with some example embodiments of the first aspect of the present disclosure, the plurality of light-emitting elements include a first light-emitting element emitting red color light, a second light-emitting element emitting green color light, and a third light-emitting element emitting blue color light, wherein the solder pattern corresponding to the first light-emitting element has a width equal to or smaller than a width of a lower end of the first light-emitting element, wherein the solder pattern corresponding to the second light-emitting element has a width greater than a width of a lower end of the second light-emitting element, wherein the solder pattern corresponding to the third light-emitting element has a width greater than a width of a lower end of the third light-emitting element.

In accordance with some example embodiments of the first aspect of the present disclosure, each of the plurality of light-emitting elements is embodied as a micro light-emitting element.

In accordance with some example embodiments of the first aspect of the present disclosure, the micro light-emitting element has a vertical structure.

In accordance with some example embodiments of the first aspect of the present disclosure, the light-emitting element is electrically connected to the first electrode by eutectic bonding.

In accordance with some example embodiments of the first aspect of the present disclosure, the plurality of light-emitting elements include a first light-emitting element emitting red color light, a second light-emitting element emitting green color light, and a third light-emitting element emitting blue color light, wherein the plurality of solder patterns include a first solder pattern corresponding to the first light-emitting element, a second solder pattern corresponding to the second light-emitting element, and a third solder pattern corresponding to the third light-emitting element, wherein a size of the first light-emitting element is greater than a size of each the second light-emitting element and the third light-emitting element, wherein the first solder pattern has a width greater than a width of each of the second solder pattern and the third solder pattern.

In accordance with some example embodiments of the first aspect of the present disclosure, the first solder pattern has a width smaller than an upper end width of the first light-emitting element and larger than a lower end width of the first light-emitting element, wherein the second solder pattern has a width smaller than an upper end width of the second light-emitting element and larger than a lower end width of the second light-emitting element, wherein the third solder pattern has a width smaller than an upper end width of the third light-emitting element and larger than a lower end width of the third light-emitting element.

In accordance with some example embodiments of the first aspect of the present disclosure, the first electrode has a mirror portion in which a surface portion of the first electrode is partially removed or etched to be recessed such that a reflective material included in the first electrode is exposed through the recess, wherein at least one of the first solder pattern, the second solder pattern, and the third solder pattern partially overlaps the mirror portion vertically.

In accordance with some example embodiments of the first aspect of the present disclosure, the plurality of light-emitting elements include a first light-emitting element emitting red color light, a second light-emitting element emitting green color light, and a third light-emitting element emitting blue color light, wherein the plurality of solder patterns include a first solder pattern corresponding to the first light-emitting element, a second solder pattern corresponding to the second light-emitting element, and a third solder pattern corresponding to the third light-emitting element, wherein a size of the first light-emitting element is greater than a size of each of the second light-emitting element and the third light-emitting element, wherein a lower electrode of the first light-emitting element has a width greater than a width of a lower electrode of each of the second light-emitting element and the third light-emitting element, wherein the first solder pattern has a width smaller than an upper end width of the first light-emitting element and smaller than or equal to a lower end width of the first light-emitting element, wherein the second solder pattern has a width smaller than an upper end width of the second light-emitting element and smaller than or equal to a lower end width of the second light-emitting element, wherein the third solder pattern has a width smaller than an upper end width of the third light-emitting element and smaller than or equal to a lower end width of the third light-emitting element.

In accordance with some example embodiments of the first aspect of the present disclosure, each of the plurality of light-emitting elements includes a main light-emitting element and a redundant light-emitting element.

In accordance with some example embodiments of the first aspect of the present disclosure, each of the plurality of first electrodes includes a first line and a second line, wherein the first line and the second line are spaced apart from each other in a first direction, and wherein the first line is connected to the main light-emitting element, and the second line is connected to the redundant light-emitting element.

In accordance with some example embodiments of the first aspect of the present disclosure, the first electrode has a mirror portion in which a surface portion of the first electrode is partially removed or etched to be recessed such that a reflective material included in the first electrode is exposed through the recess, wherein any one of the first solder pattern, the second solder pattern, and the third solder pattern non-overlaps the mirror portion vertically.

A second aspect of the present disclosure provides a display device comprising: a substrate; a driving chip disposed on the substrate; a plurality of light-emitting elements disposed on top of the driving chip and electrically connected to the driving chip; an optical insulating layer covering the plurality of light-emitting elements; and each first electrode disposed under each of the plurality of light-emitting elements, wherein each of the plurality of light-emitting elements has a groove defined in a center area of a bottom thereof, wherein a solder pattern fills the groove and protrudes downwardly beyond a bottom surface of each of the plurality of light-emitting elements such that a protruding portion of the solder pattern contacts the first electrode, wherein each of the plurality of light-emitting elements is bonded to and electrically connected to each first electrode via the solder pattern.

In accordance with some example embodiments of the second aspect of the present disclosure, the first electrode is composed of a plurality of conductive layers.

In accordance with some example embodiments of the second aspect of the present disclosure, the plurality of conductive layers include: a first conductive layer disposed on a bank; a second conductive layer disposed on the first conductive layer; a third conductive layer disposed on the second conductive layer; and a fourth conductive layer disposed on the third conductive layer.

In accordance with some example embodiments of the second aspect of the present disclosure, each of the first conductive layer, the second conductive layer, the third conductive layer, and the fourth conductive layer is made of titanium, molybdenum, aluminum, or indium tin oxide.

In accordance with some example embodiments of the second aspect of the present disclosure, the second conductive layer includes a reflective material.

In accordance with some example embodiments of the second aspect of the present disclosure, the second conductive layer includes a reflective plate including the reflective material, wherein a portion of each of the third conductive layer and the fourth conductive layer is removed or etched to expose an upper surface of the second conductive layer.

In accordance with some example embodiments of the second aspect of the present disclosure, each of the first conductive layer and the third conductive layer includes titanium or molybdenum, wherein the second conductive layer includes aluminum, wherein the fourth conductive layer is bonded to the solder pattern and includes indium tin oxide or indium zinc oxide.

In accordance with some example embodiments of the second aspect of the present disclosure, each of the plurality of light-emitting elements is embodied as a micro light-emitting element.

In accordance with some example embodiments of the second aspect of the present disclosure, the micro light-emitting element has a vertical structure.

In accordance with some example embodiments of the second aspect of the present disclosure, the light-emitting element is electrically connected to the first electrode by eutectic bonding.

In accordance with some example embodiments of the second aspect of the present disclosure, each of the plurality of light-emitting elements includes: an anode electrode disposed on the solder pattern; a first semiconductor layer disposed on the anode electrode; an active layer disposed on the first semiconductor layer; a second semiconductor layer disposed on the active layer; a cathode electrode disposed on the second semiconductor layer; and an encapsulation film disposed on at least a portion of each of the first semiconductor layer, the active layer, the second semiconductor layer, the anode electrode, and the cathode electrode.

In accordance with some example embodiments of the second aspect of the present disclosure, the first semiconductor layer and the second semiconductor layer include a nitride semiconductor containing n-type impurities and a nitride semiconductor containing p-type impurities, respectively.

In accordance with some example embodiments of the second aspect of the present disclosure, the encapsulation film surrounds at least a portion of the first semiconductor layer, at least a portion of the active layer, at least a portion of the second semiconductor layer, at least a portion of the anode electrode, and at least a portion of the cathode electrode.

In accordance with some example embodiments of the second aspect of the present disclosure, the solder pattern is made of indium (In) and the anode electrode of the light-emitting element is made of gold (Au), wherein heat and pressure are applied to the solder pattern and the anode electrode in a transfer process of the light-emitting element such that the solder pattern and the anode electrode are bonded to each other by a eutectic bond, so that the light-emitting element is bonded to the first electrode by the solder pattern.

In accordance with some example embodiments of the second aspect of the present disclosure, an upper surface the optical insulating layer is formed with a concave portion recessed downwardly.

In accordance with some example embodiments of the second aspect of the present disclosure, each of the plurality of light-emitting elements includes a main light-emitting element and a redundant light-emitting element.

In accordance with some example embodiments of the second aspect of the present disclosure, each of the plurality of first electrodes includes a first line and a second line, wherein the first line and the second line are spaced apart from each other in a first direction, and wherein the first line is connected to the main light-emitting element, and the second line is connected to the redundant light-emitting element.

In accordance with some example embodiments of the second aspect of the present disclosure, the plurality of light-emitting elements include a first light-emitting element emitting red color light, a second light-emitting element emitting green color light, and a third light-emitting element emitting blue color light, wherein the solder pattern corresponding to the first light-emitting element has a maximum width equal to or smaller than a lower end width of the first light-emitting element, wherein the solder pattern corresponding to the second light-emitting element has a maximum width greater than a lower end width of the second light-emitting element, wherein the solder pattern corresponding to the third light-emitting element has a maximum width greater than a lower end width of the third light-emitting element.

In accordance with some example embodiments of the second aspect of the present disclosure, the plurality of light-emitting elements include a first light-emitting element emitting red color light, a second light-emitting element emitting green color light, and a third light-emitting element emitting blue color light, wherein the solder pattern includes a first solder pattern corresponding to the first light-emitting element, a second solder pattern corresponding to the second light-emitting element, and a third solder pattern corresponding to the third light-emitting element, wherein a size of the first light-emitting element is greater than a size of each the second light-emitting element and the third light-emitting element, wherein the first solder pattern has a width greater than a width of each of the second solder pattern and the third solder pattern.

In accordance with some example embodiments of the second aspect of the present disclosure, the first solder pattern has a maximum width smaller than an upper end width of the first light-emitting element and larger than a lower end width of the first light-emitting element, wherein the second solder pattern has a maximum width smaller than an upper end width of the second light-emitting element and larger than a lower end width of the second light-emitting element, wherein the third solder pattern has a maximum width smaller than an upper end width of the third light-emitting element and larger than a lower end width of the third light-emitting element.

In accordance with some example embodiments of the second aspect of the present disclosure, the plurality of light-emitting elements include a first light-emitting element emitting red color light, a second light-emitting element emitting green color light, and a third light-emitting element emitting blue color light, wherein the solder pattern include a first solder pattern corresponding to the first light-emitting element, a second solder pattern corresponding to the second light-emitting element, and a third solder pattern corresponding to the third light-emitting element, wherein a size of the first light-emitting element is greater than a size of each of the second light-emitting element and the third light-emitting element, wherein a lower electrode of the first light-emitting element has a width greater than a width of a lower electrode of each of the second light-emitting element and the third light-emitting element, wherein the first solder pattern has a maximum width smaller than an upper end width of the first light-emitting element and smaller than or equal to a lower end width of the first light-emitting element, wherein the second solder pattern has a maximum width smaller than an upper end width of the second light-emitting element and smaller than or equal to a lower end width of the second light-emitting element, and wherein the third solder pattern has a maximum width smaller than an upper end width of the third light-emitting element and smaller than or equal to a lower end width of the third light-emitting element.

In accordance with some example embodiments of the another aspect of the present disclosure, provides is a display panel comprising: a substrate; a driving chip disposed on the substrate; a plurality of light-emitting elements disposed over the driving chip and electrically connected to the driving chip; a plurality of first electrodes respectively disposed under the plurality of light-emitting elements; and a plurality of solder patterns respectively disposed on upper surfaces of the plurality of first electrodes so as to respectively overlap the plurality of light-emitting elements, wherein each of the light-emitting elements is bonded to each of the first electrodes by melting of each of the solder patterns.

In accordance with some example embodiments of the another aspect of the present disclosure, provides is display panel comprising: a substrate; a driving chip disposed on the substrate; a plurality of light-emitting elements disposed over the driving chip and electrically connected to the driving chip; an optical insulating layer covering the plurality of light-emitting elements; and first electrodes each disposed under each of the plurality of light-emitting elements, wherein each of the plurality of light-emitting elements has a groove defined in a center area of a bottom thereof, wherein a solder pattern fills the groove and protrudes downwardly beyond a bottom surface of each of the plurality of light-emitting elements such that a protruding portion of the solder pattern contacts the first electrode, wherein each of the plurality of light-emitting elements is bonded to and electrically connected to each first electrode by the solder pattern.

Although some example embodiments of the present disclosure have been described above with reference to the accompanying drawings, the present disclosure may not be limited to some example embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some example embodiments as described above are not restrictive but illustrative in all respects.

What is claimed is:

1. A display device comprising:
a substrate;
a driving chip disposed on the substrate;
a plurality of light-emitting elements disposed on the driving chip and electrically connected to the driving chip;
a plurality of first electrodes respectively disposed under the plurality of light-emitting elements; and
a plurality of solder patterns respectively disposed on upper surfaces of the plurality of first electrodes so as to respectively overlap the plurality of light-emitting elements,
wherein each of the plurality of light-emitting elements is bonded to one of the plurality of first electrodes by melting of one of the plurality of solder patterns.

2. The display device of claim 1, wherein one of the plurality of solder patterns has a greater thickness than a thickness of a lower electrode of one of the plurality of light-emitting elements.

3. The display device of claim 1, wherein one of the plurality of solder patterns has a thickness smaller than a thickness of one of the plurality of first electrodes.

4. The display device of claim 1, wherein the display device further comprises a passivation layer disposed on the plurality of first electrodes,
wherein one of the plurality of solder patterns has a greater thickness than a thickness of the passivation layer.

5. The display device of claim 1, wherein the plurality of solder patterns include indium, tin, or an alloy thereof.

6. The display device of claim 4, wherein each of the plurality of solder patterns overlaps the passivation layer vertically.

7. The display device of claim 6, wherein one of the plurality of solder patterns has a width smaller than an upper end width of one of the plurality of light-emitting elements.

8. The display device of claim 4, wherein the plurality of light-emitting elements include a first light-emitting element configured to emit red color light, a second light-emitting element configured to emit green color light, and a third light-emitting element configured to emit blue color light,
wherein one of the plurality of solder patterns corresponding to the first light-emitting element has a width equal to or smaller than a lower end width of the first light-emitting element,
wherein one of the plurality of solder patterns corresponding to the second light-emitting element has a width greater than a lower end width of the second light-emitting element,
wherein one of the plurality of solder patterns corresponding to the third light-emitting element has a width greater than a lower end width of the third light-emitting element.

9. The display device of claim 1, wherein each of the plurality of light-emitting elements is embodied as a micro light-emitting element.

10. The display device of claim 9, wherein the micro light-emitting element has a vertical structure.

11. The display device of claim 1, wherein each light-emitting element is electrically connected to one of the plurality of first electrodes by eutectic bonding.

12. The display device of claim 1, wherein the plurality of light-emitting elements include a first light-emitting element configured to emit red color light, a second light-emitting element configured to emit green color light, and a third light-emitting element configured to emit blue color light,
wherein the plurality of solder patterns include a first solder pattern corresponding to the first light-emitting element, a second solder pattern corresponding to the second light-emitting element, and a third solder pattern corresponding to the third light-emitting element,
wherein a size of the first light-emitting element is greater than a size of each of the second light-emitting element and the third light-emitting element, and
wherein the first solder pattern has a width greater than a width of each of the second solder pattern and the third solder pattern.

13. The display device of claim 12, wherein the first solder pattern has a width, which is smaller than an upper end width of the first light-emitting element and larger than a lower end width of the first light-emitting element,
wherein the second solder pattern has a width, which is smaller than an upper end width of the second light-emitting element and larger than a lower end width of the second light-emitting element, and
wherein the third solder pattern has a width, which is smaller than an upper end width of the third light-emitting element and larger than a lower end width of the third light-emitting element.

14. The display device of claim 13, wherein for one of the plurality of first electrodes, the first electrode has a mirror portion in which a surface portion of the first electrode is partially removed or etched to be recessed so that a reflective material included in the first electrode is exposed through the recess, and
wherein at least one of the first solder pattern, the second solder pattern, and the third solder pattern partially overlaps the mirror portion vertically.

15. The display device of claim 1, wherein the plurality of light-emitting elements include a first light-emitting element configured to emit red color light, a second light-emitting element configured to emit green color light, and a third light-emitting element configured to emit blue color light,
wherein the plurality of solder patterns include a first solder pattern corresponding to the first light-emitting element, a second solder pattern corresponding to the second light-emitting element, and a third solder pattern corresponding to the third light-emitting element,
wherein a size of the first light-emitting element is greater than a size of each of the second light-emitting element and the third light-emitting element,
wherein a lower electrode of the first light-emitting element has a width greater than a width of a lower electrode of each of the second light-emitting element and the third light-emitting element,
wherein the first solder pattern has a width, which is smaller than an upper end width of the first light-emitting element and smaller than or equal to a lower end width of the first light-emitting element,
wherein the second solder pattern has a width, which is smaller than an upper end width of the second light-emitting element and smaller than or equal to a lower end width of the second light-emitting element, and
wherein the third solder pattern has a width, which is smaller than an upper end width of the third light-emitting element and smaller than or equal to a lower end width of the third light-emitting element.

16. The display device of claim 15, wherein for one of the plurality of first electrodes, the first electrode has a mirror portion in which a surface portion of the first electrode is partially removed or etched to be recessed so that a reflective material included in the first electrode is exposed through the recess, and
wherein any one of the first solder pattern, the second solder pattern, and the third solder pattern non-overlaps the mirror portion vertically.

17. The display device of claim 1, wherein each of the plurality of light-emitting elements includes a main light-emitting element and a redundant light-emitting element.

18. The display device of claim 17, wherein each of the plurality of first electrodes includes a first line and a second line,
wherein the first line and the second line are spaced apart from each other in a first direction, and
wherein the first line is connected to the main light-emitting element, and the second line is connected to the redundant light-emitting element.

19. A display device comprising:
a substrate;
a driving chip disposed on the substrate;
a plurality of light-emitting elements disposed on the driving chip and electrically connected to the driving chip;
an optical insulating layer covering the plurality of light-emitting elements; and
first electrodes each disposed under one of the plurality of light-emitting elements,
wherein each of the plurality of light-emitting elements has a groove defined in a center area of a bottom thereof,
wherein a solder pattern fills the groove and protrudes downwardly beyond a bottom surface of each of the plurality of light-emitting elements so that a protruding portion of the solder pattern contacts the corresponding first electrode, and
wherein each of the plurality of light-emitting elements is bonded to and electrically connected to one of the first electrodes by the solder pattern.
